(19) United States
(12) Patent Application Publication
(10) Pub. No.: US 2025/0343051 A1
(43) Pub. Date: Nov. 6, 2025

(54) METHOD FOR FORMING A SEMICONDUCTOR DEVICE HAVING A GATE MASK COMPOSING OF A SEMICONDUCTOR LAYER OVER A DIELECTRIC LAYER FORMED ON GATE ELECTRODE

(71) Applicant: Taiwan Semiconductor Manufacturing Co., Ltd., Hsinchu (TW)

(72) Inventors: Bor Chiuan Hsieh, Taoyuan City (TW); Po-Hsien Cheng, Hsinchu (TW); Tsai-Jung Ho, Xihu Township (TW); Po-Cheng Shih, Hsinchu (TW); Jr-Hung Li, Chupei City (TW); Tze-Liang Lee, Hsinchu (TW)

(21) Appl. No.: 19/269,279

(22) Filed: Jul. 15, 2025

Related U.S. Application Data
(62) Division of application No. 17/711,885, filed on Apr. 1, 2022.

(51) Int. Cl. H01L 21/311; H01L 21/768; H10D 30/01; H10D 30/62; H10D 62/83; H10D 64/01; H10D 64/62

(52) U.S. Cl. CPC H01L 21/31144; H01L 21/76802; H01L 21/76897; H10D 30/024; H10D 30/62; H10D 64/015; H01L 21/31111; H01L 21/31116; H01L 21/76831; H10D 62/83; H10D 64/62

(57) ABSTRACT

A method of forming a semiconductor device includes forming a source/drain region over a substrate; forming a first interlayer dielectric over the source/drain region; forming a gate structure over the substrate and laterally adjacent to the source/drain region; and forming a gate mask over the gate structure, the forming the gate mask comprising: etching a portion of the gate structure to form a recess relative to a top surface of the first interlayer dielectric; depositing a first dielectric layer over the gate structure in the recess and over the first interlayer dielectric; etching a portion of the first dielectric layer; depositing a semiconductor layer over the first dielectric layer in the recess; and planarizing the semiconductor layer to be coplanar with the first interlayer dielectric.

### CROSS-REFERENCE TO RELATED APPLICATIONS

This application is a divisional of U.S. patent application Ser. No. 17/711,885, filed on Apr. 1, 2022, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a fin field-effect transistor (FinFET) in a three-dimensional view, in accordance with some embodiments.

FIGS. 2-31F are views of intermediate stages in the manufacturing of FinFETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, gate masks for gate structures of transistors are formed to protect the gate structures during a process for forming contacts to source/drain regions of the transistors. The gate masks may have a hybrid film structure and may include, for example, a dielectric layer and a semiconductor layer. The dielectric layer is formed over the gate structures, and the dielectric layer is partially etched. The semiconductor layer is then formed over the etched dielectric layer, and the semiconductor layer is planarized to be coplanar with an interlayer dielectric disposed over the source/drain regions. The interlayer dielectric is etched to form contact openings to the source/drain regions. The semiconductor layer has a higher etch selectivity with the interlayer dielectric than with the dielectric layer. As a result, etching the interlayer dielectric may be performed with an increased rate, efficiency, and control, while the gate masks remain substantially unetched. In addition, forming the gate mask with the dielectric layer and the semiconductor layer ensures that the gate mask is free of voids. As a result, subsequent etching of the gate mask to form contact openings to the gate structures may be performed with increased efficiency and control while exerting little to no damage to the gate structures. Further, the dielectric layer having a low dielectric constant and remaining in the gate mask ensures that the hybrid structure of the gate mask causes little to no parasitic capacitance during functional use of the semiconductor device. These advantages result in greater yield, reduced defects, and improved performance and reliability of the resulting transistors.

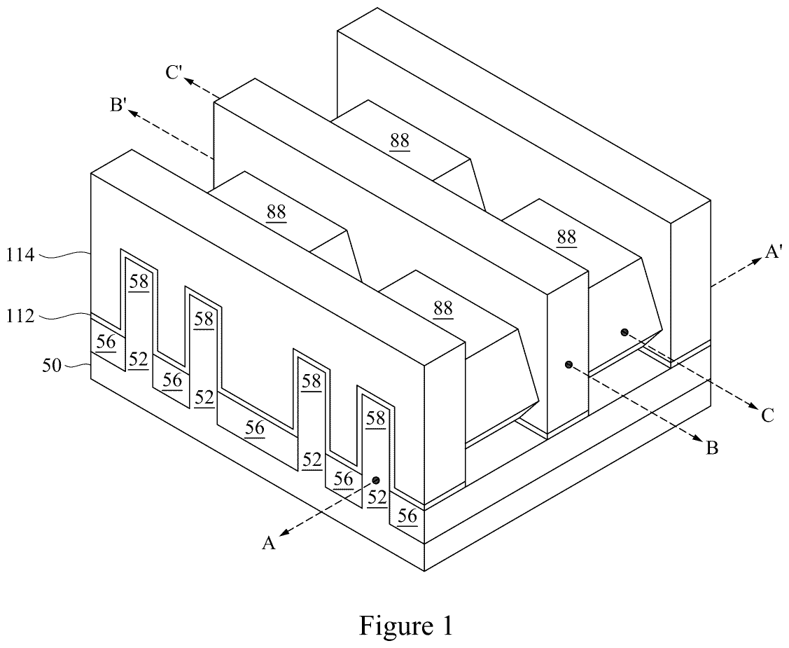

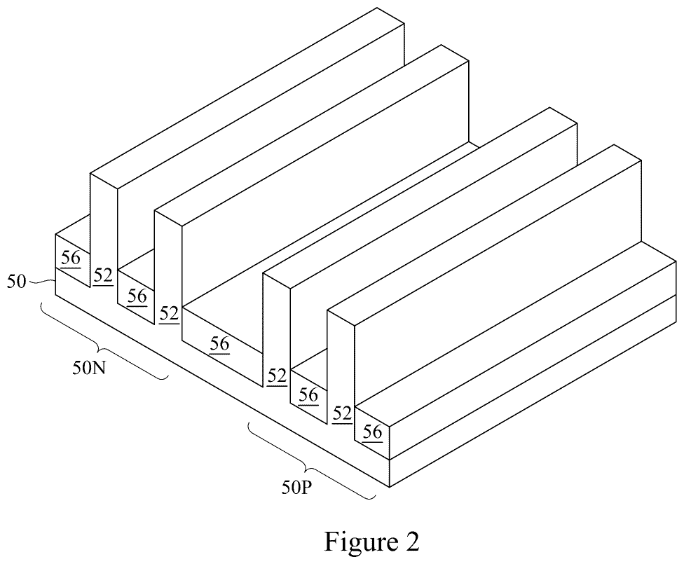

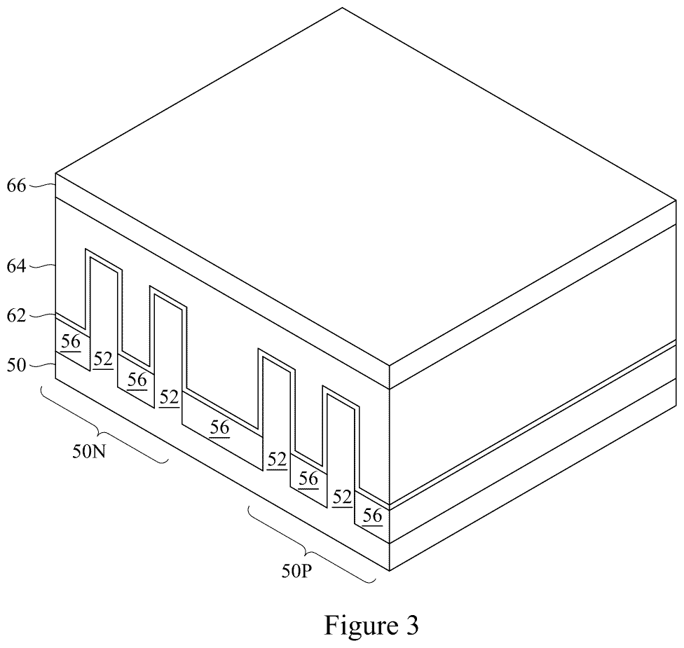

FIG. 1 illustrates an example of Fin Field-Effect Transistors (FinFETs), in accordance with some embodiments. FIG. 1 is a three-dimensional view, where some features of the FinFETs are omitted for illustration clarity. The FinFETs include fins 52 extending from a substrate 50 (e.g., a semiconductor substrate), with the fins 52 acting as channel regions 58 for the FinFETs. Isolation regions 56, such as shallow trench isolation (STI) regions, are disposed between adjacent fins 52, which may protrude above and from between adjacent isolation regions 56. Although the isolation regions 56 are described/illustrated as being separate from the substrate 50, as used herein, the term “substrate” may refer to the semiconductor substrate alone or a combination of the semiconductor substrate and the isolation regions. Additionally, although the bottom portions of the fins 52 are illustrated as being single, continuous materials with the substrate 50, the bottom portions of the fins 52 and/or the substrate 50 may include a single material or a plurality of materials. In this context, the fins 52 refer to the portion extending from between the adjacent isolation regions 56.

Gate dielectrics 112 are along sidewalls and over top surfaces of the fins 52. Gate electrodes 114 are over the gate dielectrics 112. Epitaxial source/drain regions 88 are disposed in opposite sides of the fin 52 with respect to the gate dielectrics 112 and the gate electrodes 114. The epitaxial source/drain regions 88 may be shared between various fins 52. For example, adjacent epitaxial source/drain regions 88 may be electrically connected, such as through coalescing the epitaxial source/drain regions 88 by epitaxial growth, or through coupling the epitaxial source/drain regions 88 with a same source/drain contact.

FIG. 1 further illustrates reference cross-sections that are used in later figures. Cross-section A-A′ is along a longitudinal axis of a fin 52 and in a direction of, for example, a current flow between the epitaxial source/drain regions 88 of a FinFET. Cross-section B-B′ is perpendicular to cross-section A-A′ and is along a longitudinal axis of a gate electrode 114. Cross-section C-C′ is parallel to cross-section B-B′ and extends through epitaxial source/drain regions 88 of the FinFETs. Subsequent figures refer to these reference cross-sections for clarity.

Some embodiments discussed herein are discussed in the context of FinFETs formed using a gate-last process. In other embodiments, a gate-first process may be used. Also, some embodiments contemplate aspects used in planar devices, such as planar FETs.

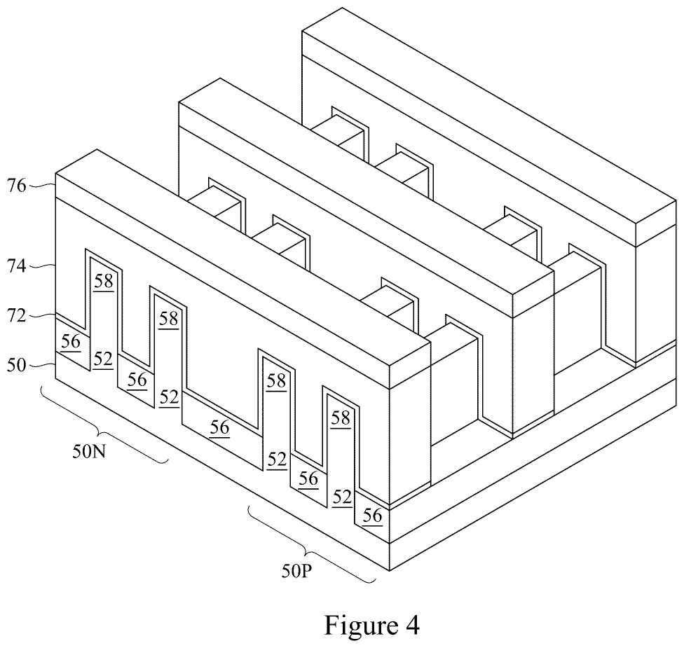

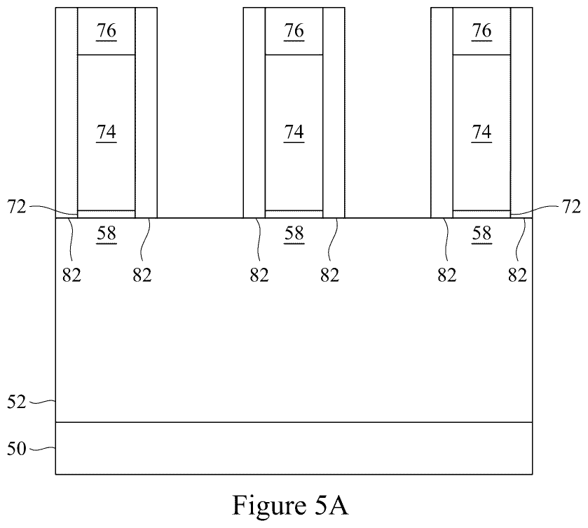

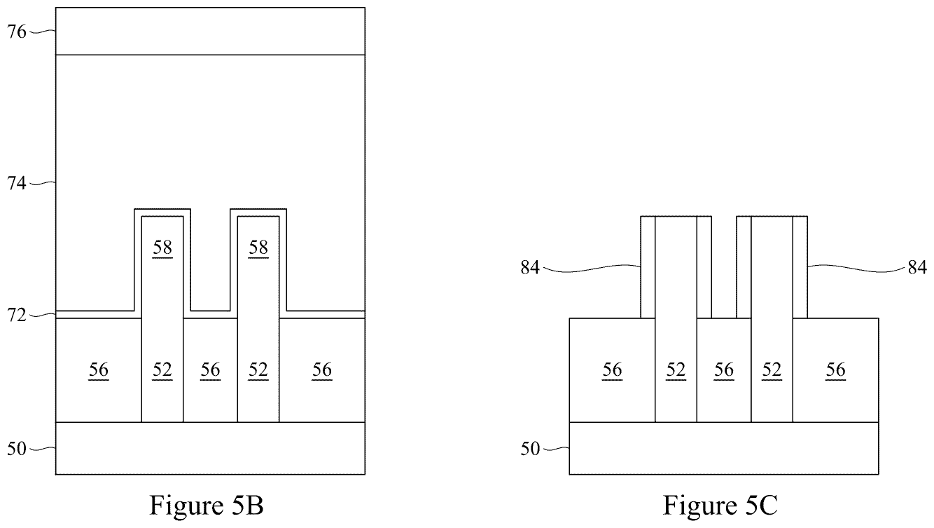

FIGS. 2-31F are views of intermediate stages in the manufacturing of FinFETs, in accordance with some embodiments. FIGS. 2, 3, and 4, are three-dimensional views showing a similar three-dimensional view as FIG. 1. FIGS. 5A, 6A, 7A, 8A, 9A, 10A, 11A, 12A, 13A, 13D, 14A, 14D, 15A, 15D, 16A, 16D, 16E, 17A, 17D, 18A, 18D, 19A, 19D, 20A, 20D, 21A, 21D, 22A, 22D, 23A, 23D, 24A, 24D, 25A, 25D, 26A, 26D, 27A, 27D, 28A, 28D, 29A, 29D, 30A, 30D, 31A, 31B, 31D, and 31E are cross-sectional views illustrated along a similar cross-section as reference cross-section A-A′ in FIG. 1. FIGS. 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, and 30B are cross-sectional views illustrated along a similar cross-section as reference cross-section B-B′ in FIG. 1. FIGS. 5C, 6C, 7C, 8C, 9C, 10C, 11C, 12C, 13C, 14C, 15C, 16C, 17C, 18C, 19C, 20C, 21C, 22C, 23C, 24C, 25C, 26C, 27C, 28C, 29C, and 30C are cross-sectional views illustrated along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type impurity) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 50 has an n-type region 50N and a p-type region 50P. The n-type region 50N can be for forming n-type devices, such as NMOS transistors, e.g., n-type FinFETs, and the p-type region 50P can be for forming p-type devices, such as PMOS transistors, e.g., p-type FinFETs. The n-type region 50N may be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Fins 52 are formed in the substrate 50. The fins 52 are semiconductor strips. The fins 52 may be formed in the substrate 50 by etching trenches in the substrate 50. The etching may be any acceptable etching process, such as a reactive ion etch (RIE), neutral beam etch (NBE), the like, or a combination thereof. The etching process may be anisotropic.

The fins 52 may be patterned by any suitable method. For example, the fins 52 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as masks to pattern the fins 52. In some embodiments, the mask (or other layer) may remain on the fins 52.

STI regions 56 are formed over the substrate 50 and between adjacent fins 52. The STI regions 56 are disposed around lower portions of the fins 52 such that upper portions of the fins 52 protrude from between adjacent STI regions 56. In other words, the upper portions of the fins 52 extend above the top surfaces of the STI regions 56. The STI regions 56 separate the features of adjacent devices.

The STI regions 56 may be formed by any suitable method. For example, an insulation material can be formed over the substrate 50 and between adjacent fins 52. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. Although the STI regions 56 are each illustrated as a single layer, some embodiments may utilize multiple layers. For example, in some embodiments a liner (not separately illustrated) may first be formed along surfaces of the substrate 50 and the fins 52. Thereafter, an insulation material, such as those previously described may be formed over the liner. In an embodiment, the insulation material is formed such that excess insulation material covers the fins 52. A removal process is then applied to the insulation material to remove excess insulation material over the fins 52. In some embodiments, a planarization process such as a chemical mechanical polish (CMP), an etch-back process, combinations thereof, or the like may be utilized. In embodiments in which a mask remains on the fins 52, the planarization process may expose the mask or remove the mask. After the planarization process, the top surfaces of the insulation material and the mask (if present) or the fins 52 are coplanar (within process variations). Accordingly, the top surfaces of the mask (if present) or the fins 52 are exposed through the insulation material. In the illustrated embodiment, no mask remains on the fins 52. The insulation material is then recessed to form the STI regions 56. The insulation material is recessed such that upper portions of the fins 52 protrude from between adjacent portions of the insulation material. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The insulation material may be recessed using any acceptable etching process, such as one that is selective to the material of the insulation material (e.g., selectively etches the insulation material of the STI regions 56 at a faster rate than the material of the fins 52). For example, an oxide removal may be performed using dilute hydrofluoric (dHF) acid.

The process previously described is just one example of how the fins 52 and the STI regions 56 may be formed. In some embodiments, the fins 52 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 52. In some embodiments where epitaxial structures are epitaxially grown, the epitaxially grown materials may be in situ doped during growth, which may obviate prior and/or subsequent implantations, although in situ and implantation doping may be used together.

Further, it may be advantageous to epitaxially grow a material in the n-type region 50N different from the material in the p-type region 50P. In various embodiments, upper portions of the fins 52 may be formed of silicon-germanium (SiₓGe₁₋ₓ, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

Further, appropriate wells (not separately illustrated) may be formed in the fins 52 and/or the substrate 50. The wells may have a conductivity type opposite from a conductivity type of source/drain regions that will be subsequently formed in each of the n-type region 50N and the p-type region 50P. In some embodiments, a p-type well is formed in the n-type region 50N, and an n-type well is formed in the p-type region 50P. In some embodiments, a p-type well or an n-type well is formed in both the n-type region 50N and the p-type region 50P.

In embodiments with different well types, different implant steps for the n-type region 50N and the p-type region 50P may be achieved using a mask (not separately illustrated) such as a photoresist. For example, a photoresist may be formed over the fins 52 and the STI regions 56 in the n-type region 50N. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in the range of about 10¹³ cm⁻³ to about 10¹⁴ cm⁻³. After the implant, the photoresist is removed, such as by any acceptable ashing process.

Following or prior to the implanting of the p-type region 50P, a mask (not separately illustrated) such as a photoresist is formed over the fins 52 and the STI regions 56 in the p-type region 50P. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in the range of about 10¹³ cm⁻³ to about 10¹⁴ cm⁻³. After the implant, the photoresist is removed, such as by any acceptable ashing process.

After the implants of the n-type region 50N and the p-type region 50P, an anneal may be performed to repair implant damage and to activate the p-type and/or n-type impurities that were implanted. In some embodiments where epitaxial structures are epitaxially grown for the fins 52, the grown materials may be in situ doped during growth, which may obviate the implantations, although in situ and implantation doping may be used together.

In FIG. 3, a dummy dielectric layer 62 is formed on the fins 52. The dummy dielectric layer 62 may be formed of a dielectric material such as silicon oxide, silicon nitride, a combination thereof, or the like, which may be deposited or thermally grown according to acceptable techniques. A dummy gate layer 64 is formed over the dummy dielectric layer 62, and a mask layer 66 is formed over the dummy gate layer 64. The dummy gate layer 64 may be deposited over the dummy dielectric layer 62 and then planarized, such as by a CMP. The mask layer 66 may be deposited over the dummy gate layer 64. The dummy gate layer 64 may be formed of a conductive or non-conductive material, such as amorphous silicon, polycrystalline-silicon (polysilicon), polycrystalline silicon-germanium (poly-SiGe), a metal, a metallic nitride, a metallic silicide, a metallic oxide, or the like, which may be deposited by physical vapor deposition (PVD), CVD, or the like. The dummy gate layer 64 may be formed of material(s) that have a high etch selectivity from the etching of insulation materials, e.g., the STI regions 56 and/or the dummy dielectric layer 62. The mask layer 66 may be formed of a dielectric material such as silicon nitride, silicon oxynitride, or the like. In this example, a single dummy gate layer 64 and a single mask layer 66 are formed across the n-type region 50N and the p-type region 50P. In the illustrated embodiment, the dummy dielectric layer 62 covers the fins 52 and the STI regions 56, such that the dummy dielectric layer 62 extends over the STI regions 56 and between the dummy gate layer 64 and the STI regions 56. In another embodiment, the dummy dielectric layer 62 covers only the fins 52.

In FIG. 4, the mask layer 66 is patterned using acceptable photolithography and etching techniques to form masks 76. The pattern of the masks 76 is then transferred to the dummy gate layer 64 by any acceptable etching technique to form dummy gates 74. The pattern of the masks 76 may optionally be further transferred to the dummy dielectric layer 62 by any acceptable etching technique to form dummy dielectrics 72. The dummy gates 74 cover respective channel regions 58 of the fins 52. The pattern of the masks 76 may be used to physically separate adjacent dummy gates 74. The dummy gates 74 may also have lengthwise directions substantially perpendicular (within process variations) to the lengthwise directions of the fins 52. The masks 76 may be removed during the patterning of the dummy gate 74, or may be removed during subsequent processing.

FIGS. 5A-30D illustrate various additional steps in the manufacturing of embodiment devices. FIGS. 5A-30D illustrate features in either of the n-type region 50N and the p-type region 50P. For example, the structures illustrated may be applicable to both the n-type region 50N and the p-type region 50P. Differences (if any) in the structures of the n-type region 50N and the p-type region 50P are described in the text accompanying each figure.

In FIGS. 5A-5C, gate spacers 82 are formed over the fins 52, on exposed sidewalls of the masks 76 (if present), the dummy gates 74, and the dummy dielectrics 72. The gate spacers 82 may be formed by conformally depositing one or more dielectric material(s) and subsequently etching the dielectric material(s). Acceptable dielectric materials may include silicon oxide, silicon nitride, silicon oxynitride, silicon oxycarbonitride, or the like, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etching process, such as a dry etch, a wet etch, the like, or a combination thereof, may be performed to pattern the dielectric material(s). The etching may be anisotropic. The dielectric material(s), when etched, have portions left on the sidewalls of the dummy gates 74 (thus forming the gate spacers 82). As will be subsequently described in greater detail, in some embodiments the etch used to form the gate spacers 82 is adjusted so that the dielectric material(s), when etched, also have portions left on the sidewalls of the fins 52 (thus forming fin spacers 84). After etching, the fin spacers 84 (if present) and the gate spacers 82 can have straight sidewalls (as illustrated) or can have curved sidewalls (not separately illustrated).

Further, implants may be performed to form lightly doped source/drain (LDD) regions (not separately illustrated). In the embodiments with different device types, similar to the implants for the wells previously described, a mask (not separately illustrated) such as a photoresist may be formed over the n-type region 50N, while exposing the p-type region 50P, and appropriate type (e.g., p-type) impurities may be implanted into the fins 52 exposed in the p-type region 50P. The mask may then be removed. Subsequently, a mask (not separately illustrated) such as a photoresist may be formed over the p-type region 50P while exposing the n-type region 50N, and appropriate type impurities (e.g., n-type) may be implanted into the fins 52 exposed in the n-type region 50N. The mask may then be removed. The n-type impurities may be any of the n-type impurities previously described, and the p-type impurities may be any of the p-type impurities previously described. During the implanting, the channel regions 58 remain covered by the dummy gates 74, so that the channel regions 58 remain substantially free of the impurity implanted to form the LDD regions. The LDD regions may have a concentration of impurities in the range of about 10¹⁵ cm⁻³ to about 10¹⁹ cm⁻³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

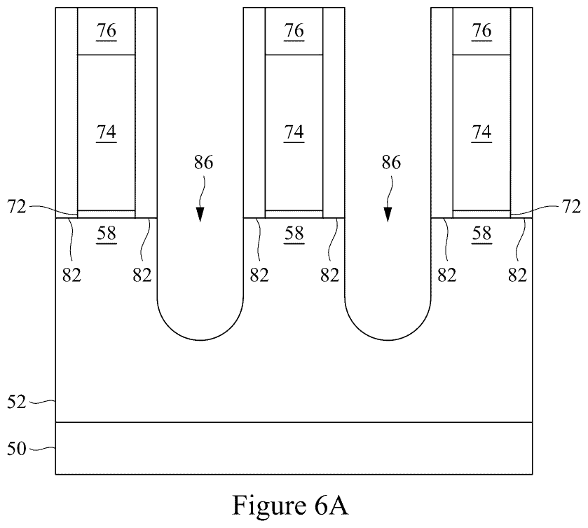

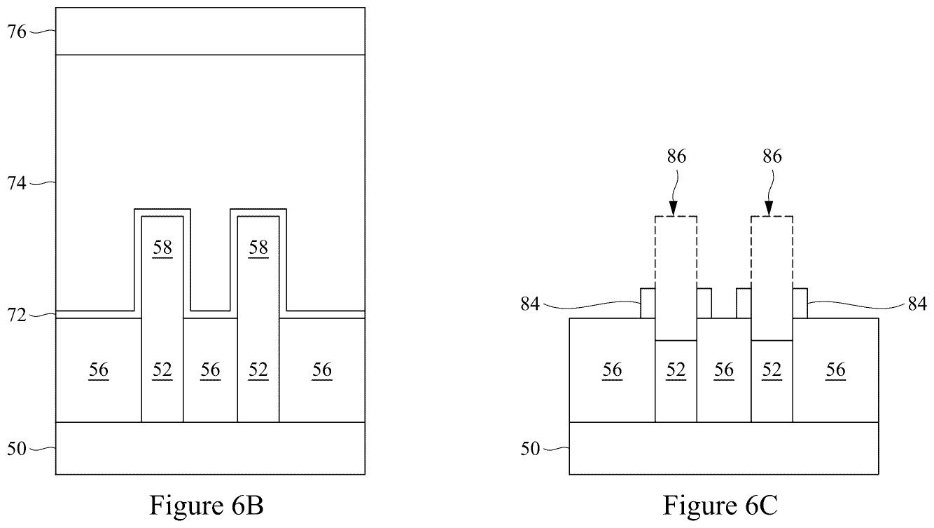

In FIGS. 6A-6C, source/drain recesses 86 are formed in the fins 52. In the illustrated embodiment, the source/drain recesses 86 extend into the fins 52. The source/drain recesses 86 may also extend into the substrate 50. In various embodiments, the source/drain recesses 86 may extend to a top surface of the substrate 50 without etching the substrate 50; the fins 52 may be etched such that bottom surfaces of the source/drain recesses 86 are disposed below the top surfaces of the STI regions 56; or the like. The source/drain recesses 86 may be formed by etching the fins 52 using an anisotropic etching processes, such as a RIE, a NBE, or the like. The gate spacers 82 and the dummy gates 74 collectively mask portions of the fins 52 during the etching processes used to form the source/drain recesses 86. Timed etch processes may be used to stop the etching of the source/drain recesses 86 after the source/drain recesses 86 reach a desired depth. In some embodiments, the fin spacers 84 are also recessed until they are a desired height. Controlling the height of the fin spacers 84 allows the dimensions of the subsequently grown source/drain regions to be controlled.

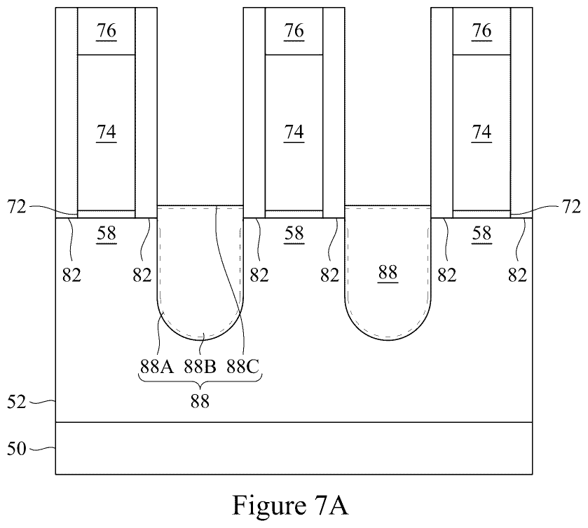

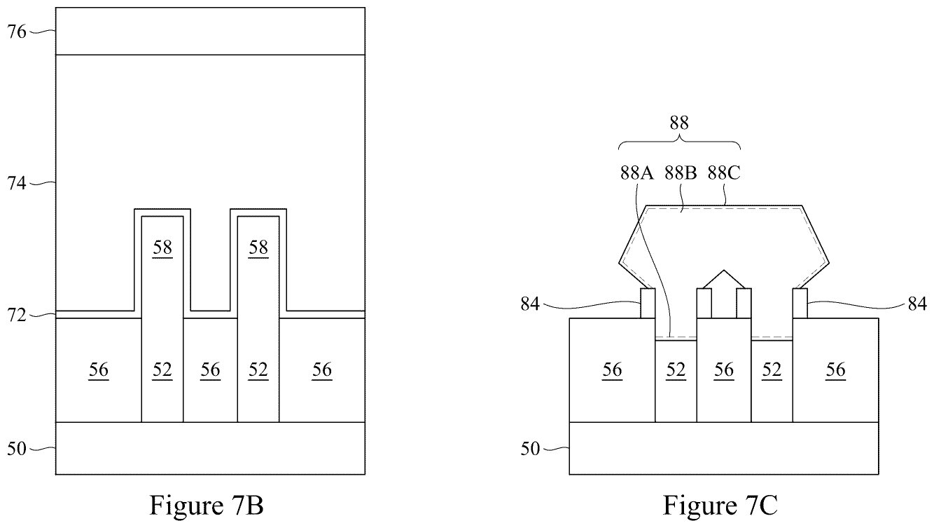

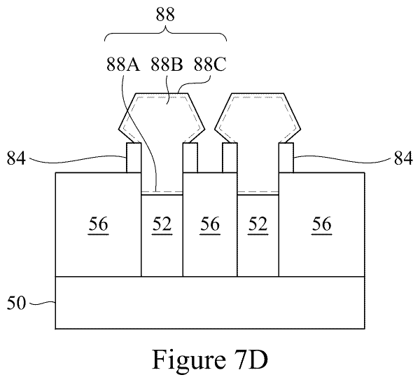

In FIGS. 7A-7D, epitaxial source/drain regions 88 are formed in the source/drain recesses 86. The epitaxial source/drain regions 88 are thus disposed in the fins 52 such that each dummy gate 74 (and corresponding channel region 58) is between respective adjacent pairs of the epitaxial source/drain regions 88. The epitaxial source/drain regions 88 thus adjoin the channel regions 58. In some embodiments, the gate spacers 82 are used to separate the epitaxial source/drain regions 88 from the dummy gates 74 by an appropriate lateral distance so that the epitaxial source/drain regions 88 do not short out with subsequently formed gates of the resulting FinFETs. A material of the epitaxial source/drain regions 88 may be selected to exert stress in the respective channel regions 58, thereby improving performance.

The epitaxial source/drain regions 88 in the n-type region 50N may be formed by masking the p-type region 50P. Then, the epitaxial source/drain regions 88 in the n-type region 50N are epitaxially grown in the source/drain recesses 86 in the n-type region 50N. The epitaxial source/drain regions 88 may include any acceptable material appropriate for n-type devices. For example, if the fins 52 are silicon, the epitaxial source/drain regions 88 in the n-type region 50N may include materials exerting a tensile stress on the channel regions 58 (e.g., forming a tensile strain therein), such as silicon, silicon carbide, phosphorous doped silicon carbide, silicon phosphide, or the like. The epitaxial source/drain regions 88 in the n-type region 50N may be referred to as “n-type source/drain regions.” The epitaxial source/drain regions 88 in the n-type region 50N may have surfaces raised from respective surfaces of the fins 52 and may have facets.

The epitaxial source/drain regions 88 in the p-type region 50P may be formed by masking the n-type region 50N. Then, the epitaxial source/drain regions 88 in the p-type region 50P are epitaxially grown in the source/drain recesses 86 in the p-type region 50P. The epitaxial source/drain regions 88 may include any acceptable material appropriate for p-type devices. For example, if the fins 52 are silicon, the epitaxial source/drain regions 88 in the p-type region 50P may include materials exerting a compressive stress on the channel regions 58 (e.g., forming a compressive strain therein), such as silicon germanium, boron doped silicon germanium, germanium, germanium tin, or the like. The epitaxial source/drain regions 88 in the p-type region 50P may be referred to as “p-type source/drain regions.” The epitaxial source/drain regions 88 in the p-type region 50P may have surfaces raised from respective surfaces of the fins 52 and may have facets.

The epitaxial source/drain regions 88 and/or the fins 52 may be implanted with impurities to form source/drain regions, similar to the process previously described for forming LDD regions, followed by an anneal. The source/drain regions may have an impurity concentration in the range of about 10¹⁹ cm⁻³ to about 10²¹ cm⁻³. The n-type and/or p-type impurities for source/drain regions may be any of the impurities previously described. In some embodiments, the epitaxial source/drain regions 88 may be in situ doped during growth.

As a result of the epitaxy processes used to form the epitaxial source/drain regions 88 in the n-type region 50N and the p-type region 50P, upper surfaces of the epitaxial source/drain regions 88 have facets which expand laterally outward beyond sidewalls of the fins 52. In some embodiments, these facets cause adjacent epitaxial source/drain regions 88 of a same FinFET to merge as illustrated by FIG. 7C. In some embodiments, adjacent epitaxial source/drain regions 88 remain separated after the epitaxy process is completed as illustrated by FIG. 7D. In the illustrated embodiments, remaining portions of the fin spacers 84 cover a portion of the sidewalls of the fins 52 that extend above the STI regions 56, thereby blocking or inhibiting the epitaxial growth. In another embodiment, the spacer etch used to form the gate spacers 82 is adjusted to not form the fin spacers 84 (e.g., to remove the fin spacers 84), so as to allow the epitaxial source/drain regions 88 to extend to the surface of the STI regions 56.

The epitaxial source/drain regions 88 may include one or more semiconductor material layers. For example, the epitaxial source/drain regions 88 may each include a liner layer 88A, a main layer 88B, and a finishing layer 88C (or more generally, a first semiconductor material layer, a second semiconductor material layer, and a third semiconductor material layer). Any number of semiconductor material layers may be used for the epitaxial source/drain regions 88. The liner layers 88A, the main layers 88B, and the finishing layers 88C may be formed of different semiconductor materials and may be doped to different impurity concentrations. In some embodiments, the main layers 88B have a greater concentration of impurities than the finishing layers 88C, and the finishing layers 88C have a greater concentration of impurities than the liner layers 88A. In embodiments in which the epitaxial source/drain regions 88 include three semiconductor material layers, the liner layers 88A may be grown in the source/drain recesses 86, the main layers 88B may be grown on the liner layers 88A, and the finishing layers 88C may be grown on the main layers 88B. Forming the liner layers 88A with a lesser concentration of impurities than the main layers 88B may increase adhesion in the source/drain recesses 86, and forming the finishing layers 88C with a lesser concentration of impurities than the main layers 88B may reduce out-diffusion of dopants from the main layers 88B during subsequent processing.

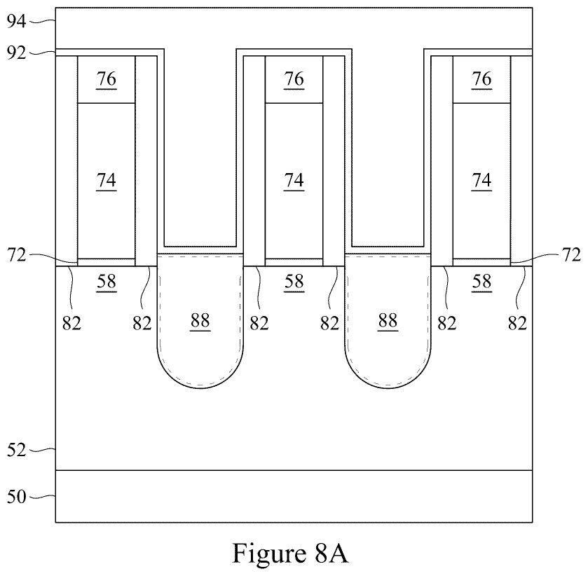

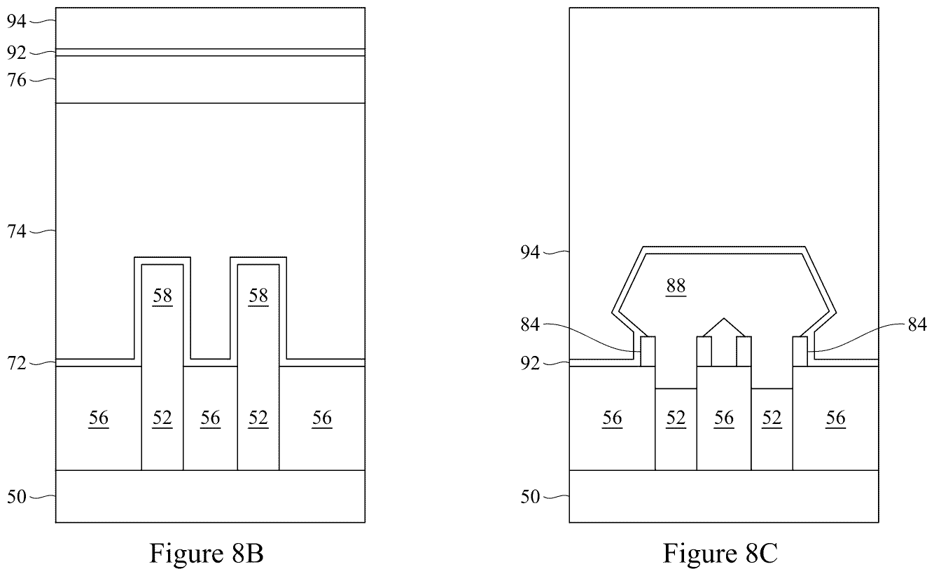

In FIGS. 8A-8C, a first inter-layer dielectric (ILD) 94 is deposited over the epitaxial source/drain regions 88, the gate spacers 82, and the masks 76 (if present) or the dummy gates 74. The first ILD 94 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 92 is formed between the first ILD 94 and the epitaxial source/drain regions 88, the gate spacers 82, and the masks 76 (if present) or the dummy gates 74. The CESL 92 may be formed of a dielectric material, such as silicon nitride, silicon oxide, silicon oxynitride, or the like, having a high etch selectivity from the etching of the first ILD 94. The CESL 92 may be formed by an any suitable method, such as CVD, ALD, or the like.

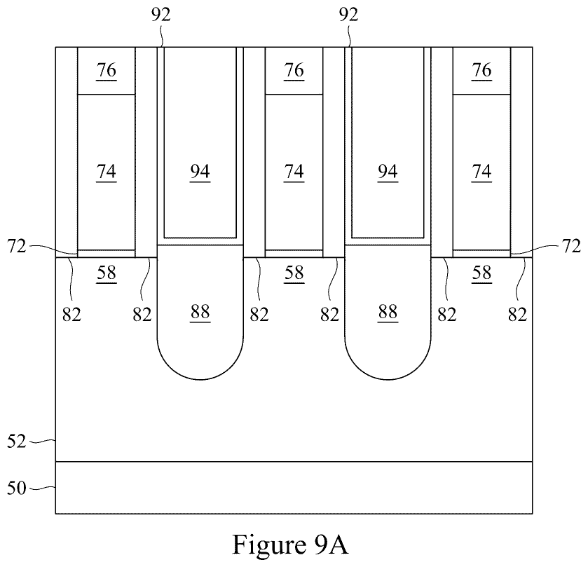

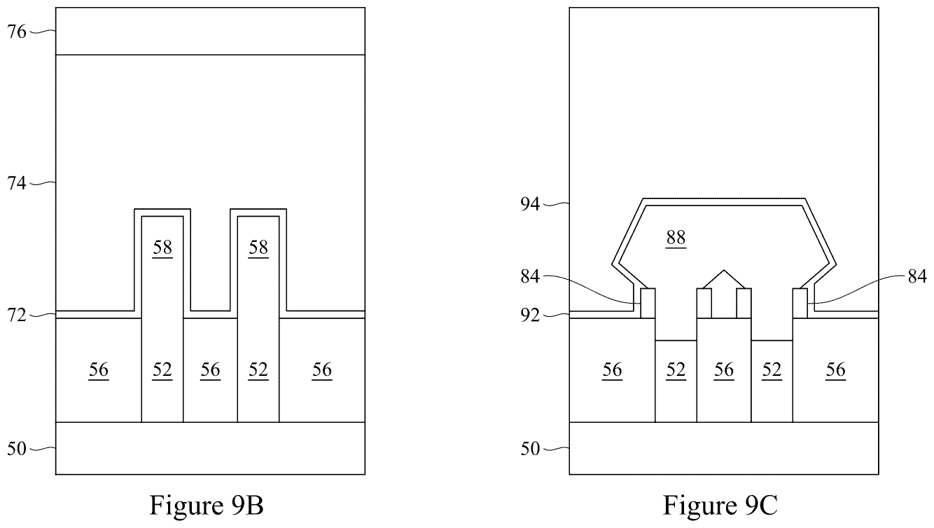

In FIGS. 9A-9C, a removal process is performed to level the top surfaces of the first ILD 94 with the top surfaces of the masks 76 (if present) or the dummy gates 74. In some embodiments, a planarization process such as a chemical mechanical polish (CMP), an etch-back process, combinations thereof, or the like may be utilized. The planarization process may also remove the masks 76 on the dummy gates 74, and portions of the gate spacers 82 along sidewalls of the masks 76. After the planarization process, the top surfaces of the first ILD 94, the CESL 92, the gate spacers 82, and the masks 76 (if present) or the dummy gates 74 are coplanar (within process variations). Also after the planarization process, the gate spacers 82 have a uniform height. Accordingly, the top surfaces of the masks 76 (if present) or the dummy gates 74 are exposed through the first ILD 94. In the illustrated embodiment, the masks 76 remain, and the planarization process levels the top surfaces of the first ILD 94 to be coplanar with the top surfaces of the masks 76.

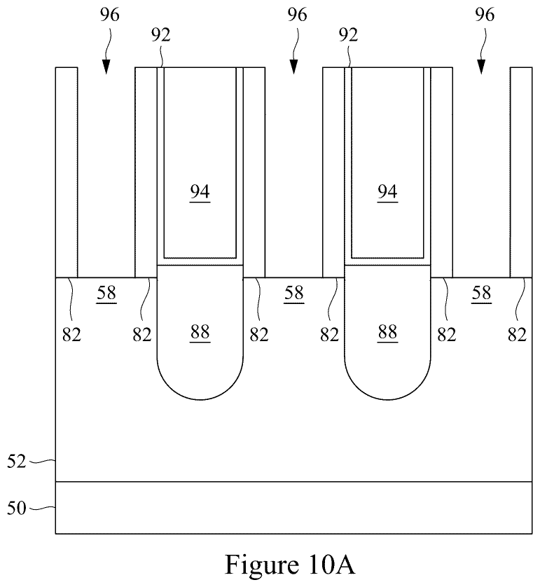

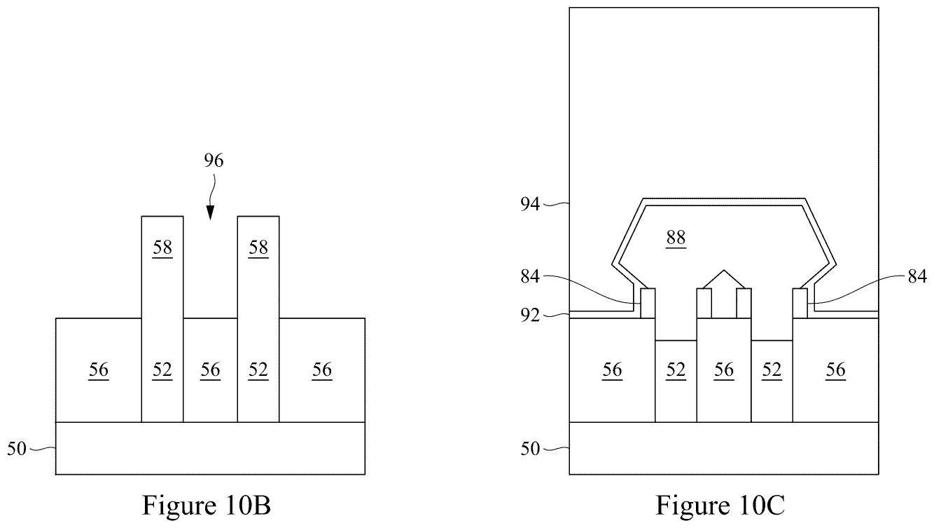

In FIGS. 10A-10C, the masks 76 (if present) and the dummy gates 74 are removed in an etching process, so that recesses 96 are formed. Portions of the dummy dielectrics 72 in the recesses 96 may also be removed. In some embodiments, only the dummy gates 74 are removed and the dummy dielectrics 72 remain and are exposed by the recesses 96. In some embodiments, the dummy dielectrics 72 are removed from recesses 96 in a first region of a die (e.g., a core logic region) and remain in recesses 96 in a second region of the die (e.g., an input/output region). In some embodiments, the dummy gates 74 are removed by an anisotropic dry etch process. For example, the etching process may include a dry etch process using reaction gas(es) that selectively etch the dummy gates 74 at a faster rate than the first ILD 94 or the gate spacers 82. During the removal, the dummy dielectrics 72 may be used as etch stop layers when the dummy gates 74 are etched. The dummy dielectrics 72 may then be optionally removed after the removal of the dummy gates 74. Each recess 96 exposes and/or overlies a channel region 58 of a respective fin 52.

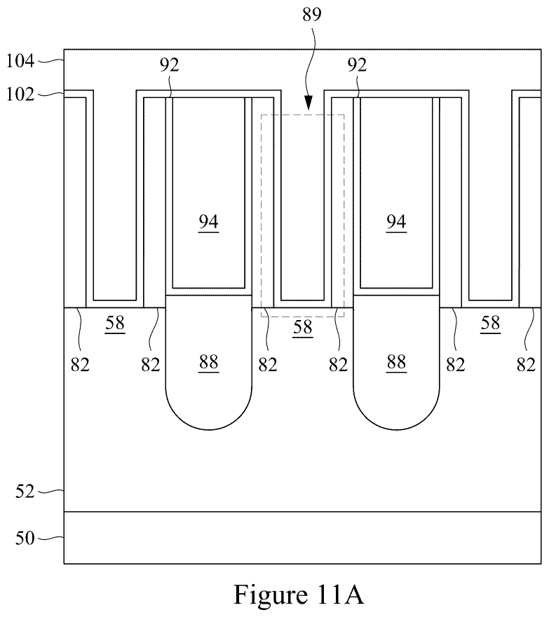

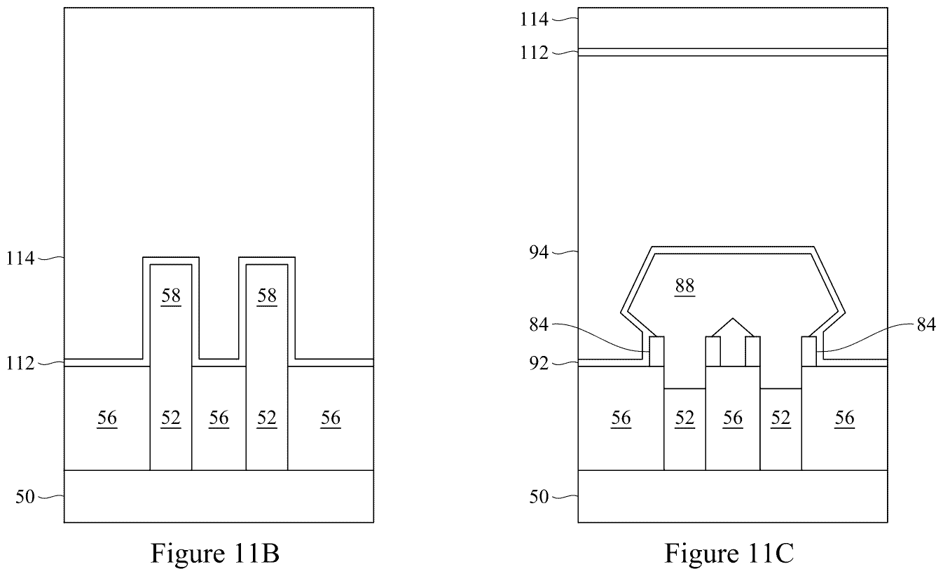

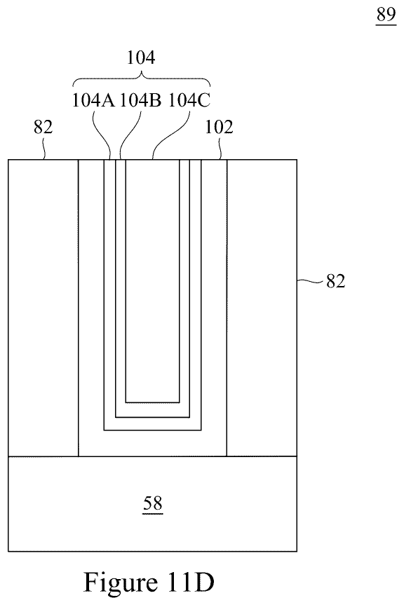

In FIGS. 11A-11D, a gate dielectric layer 102 is formed in the recesses 96. A gate electrode layer 104 is formed on the gate dielectric layer 102. The gate dielectric layer 102 and the gate electrode layer 104 are layers for replacement gates, and each extend along sidewalls and over top surfaces of the channel regions 58.

The gate dielectric layer 102 is disposed on the sidewalls and/or the top surfaces of the fins 52 and on the sidewalls of the gate spacers 82. The gate dielectric layer 102 may also be formed on the top surfaces of the first ILD 94 and the gate spacers 82. The gate dielectric layer 102 may include an oxide such as silicon oxide or a metal oxide, a silicate such as a metal silicate, combinations thereof, multi-layers thereof, or the like. The gate dielectric layer 102 may include a dielectric material having a k-value greater than about 7.0 (e.g., a high-k dielectric material), such as a metal oxide or a silicate of hafnium, aluminum, zirconium, lanthanum, manganese, barium, titanium, lead, and combinations thereof. The formation methods of the gate dielectric layer 102 may include molecular-beam deposition (MBD), ALD, PECVD, and the like. In embodiments where portions of the dummy dielectrics 72 remain in the recesses 96, the gate dielectric layer 102 includes a material of the dummy dielectrics 72 (e.g., silicon oxide). Although a single-layered gate dielectric layer 102 is illustrated, the gate dielectric layer 102 may include any number of interfacial layers and any number of main layers. For example, the gate dielectric layer 102 may include an interfacial layer and an overlying high-k dielectric layer.

The gate electrode layer 104 may include a metal-containing material such as titanium nitride, titanium oxide, tantalum nitride, tantalum carbide, tungsten, cobalt, ruthenium, aluminum, combinations thereof, multi-layers thereof, or the like. For example, although a single layer gate electrode 104 is illustrated in FIG. 11A, the gate electrode 104 may comprise any number of liner layers 104A, any number of work function tuning layers 104B, and a fill material 104C as illustrated by FIG. 11D. After the filling of the recesses 96, a planarization process, such as a CMP, may be performed to remove the excess portions of the gate dielectric layers 102 and the material of the gate electrodes 104, which excess portions are over the top surface of the ILD 94. The remaining portions of material of the gate electrodes 104 and the gate dielectric layers 102 thus form replacement gates of the resulting FinFETs. The gate electrodes 104 and the gate dielectric layers 102 may be collectively referred to as a “gate stack.” The gate and the gate stacks may extend along sidewalls of a channel region 58 of the fins 52.

The formation of the gate dielectric layer 102 in the n-type region 50N and the p-type region 50P may occur simultaneously such that the gate dielectric layer 102 in each region is formed of the same material(s), and the formation of the gate electrode layer 104 may occur simultaneously such that the gate electrode layer 104 in each region is formed of the same material(s). In some embodiments, the gate dielectric layers 102 in each region may be formed by distinct processes, such that the gate dielectric layers 102 may be different materials and/or have a different number of layers, and/or the gate electrode layers 104 in each region may be formed by distinct processes, such that the gate electrode layers 104 may be different materials and/or have a different number of layers. Various masking steps may be used to mask and expose appropriate regions when using distinct processes.

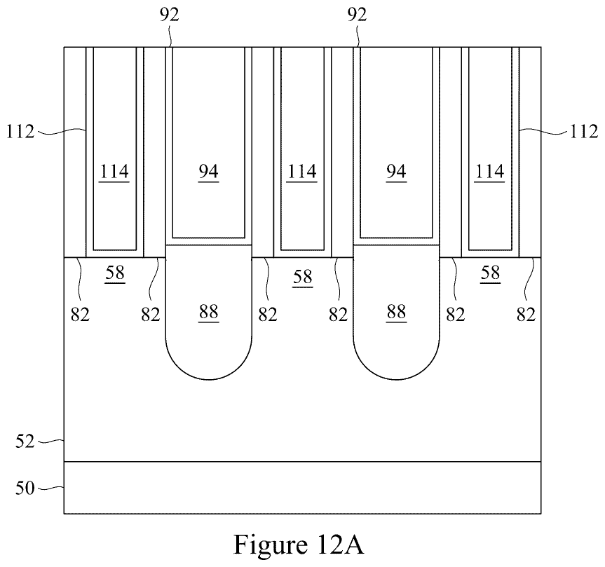

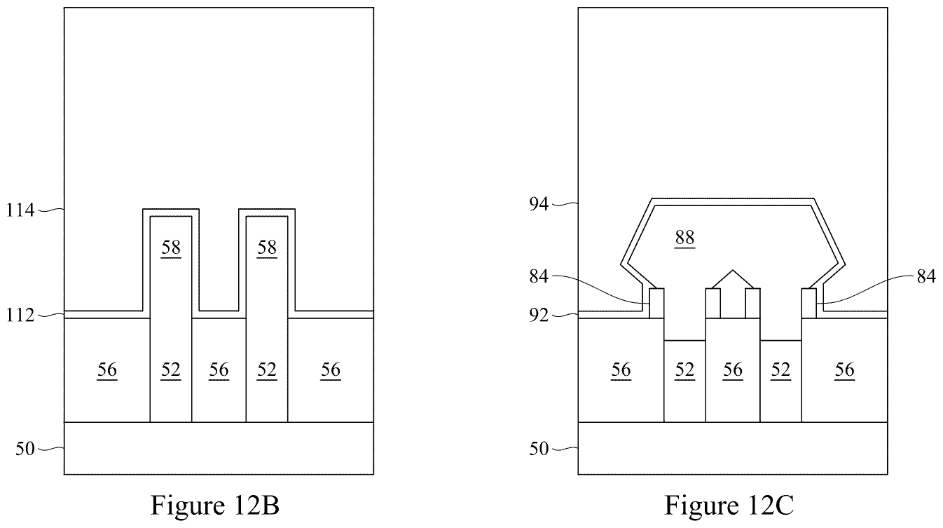

In FIGS. 12A-12C, a removal process is performed to remove the excess portions of the materials of the gate dielectric layer 102 and the gate electrode layer 104, which excess portions are over the top surfaces of the first ILD 94, the CESL 92, and the gate spacers 82, thereby forming gate dielectrics 112 and gate electrodes 114. In some embodiments, a planarization process such as a CMP, an etch-back process, combinations thereof, or the like may be utilized. The gate dielectric layer 102, when planarized, has portions left in the recesses 96 (thus forming the gate dielectrics 112). The gate electrode layer 104, when planarized, has portions left in the recesses 96 (thus forming the gate electrodes 114). After the planarization process, the top surfaces of the gate spacers 82, the CESL 92, the first ILD 94, the gate dielectrics 112, and the gate electrodes 114 are coplanar (within process variations). The gate dielectrics 112 and the gate electrodes 114 form replacement gates of the resulting FinFETs. Each respective pair of a gate dielectric 112 and a gate electrode 114 may be collectively referred to as a “gate structure.” The gate structures each extend along top surfaces, sidewalls, and bottom surfaces of a channel region 58 of fins 52.

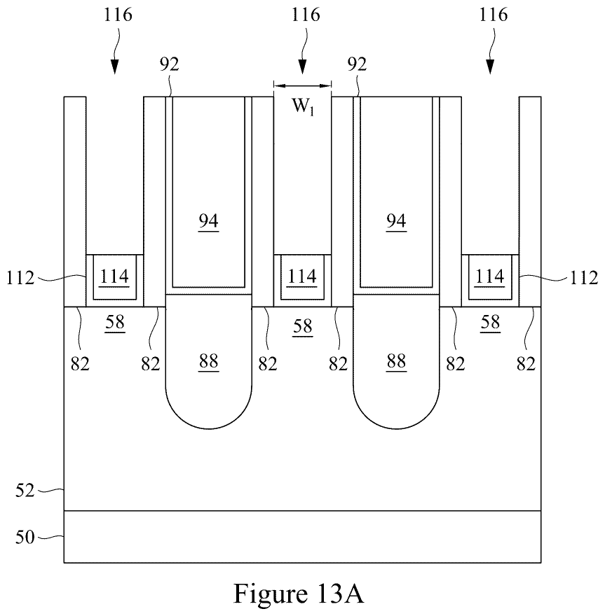

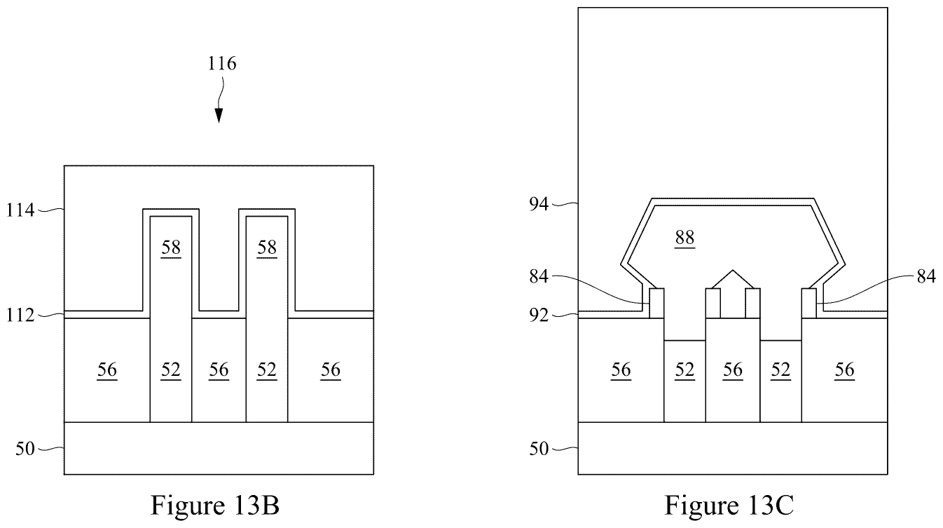

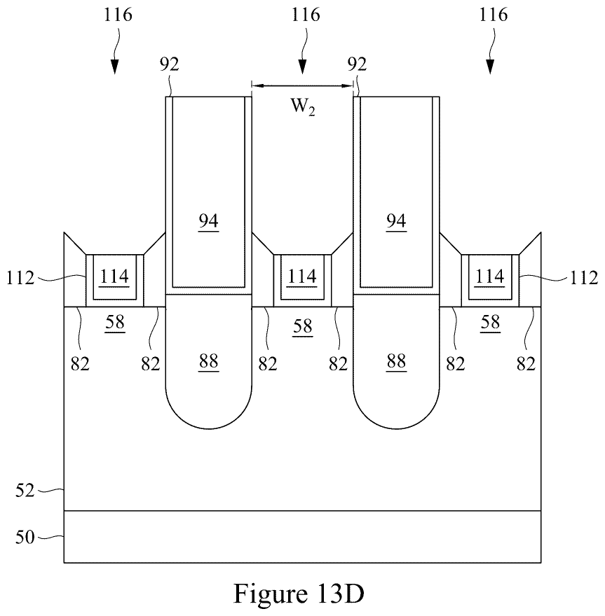

In FIGS. 13A-13D, the gate structures (including the gate dielectrics 112 and the gate electrodes 114) are recessed to form recesses 116 relative to a top surface of the first ILD 94 and directly over the gate structures. The gate structures may be recessed using any acceptable etching process, such as one that is selective to the material of the gate structures (e.g., selectively etches the materials of the gate dielectrics 112 and the gate electrodes 114 at a faster rate than the materials of the first ILD 94 and the CESL 92). For example, the recesses 116 may have a width W₁ ranging from 10 nm to 30 nm.

Referring to FIG. 13D, in some embodiments, the gate spacers 82 may also be recessed with the gate structures. When the gate spacers 82 are recessed, they may be recessed the same amount as the gate structures, or may be recessed by a different amount. As illustrated, upper portions of the recesses 116 may be wider than in the embodiments relating to FIG. 13A, and the gate spacers 82 and the gate structures may give the bottom of the recesses 116 a concave shape. For example, the recesses 116 may have a width W₂ ranging from 20 nm to 40 nm. Note that FIGS. 13B and 13C may be applicable and analogous to these embodiments.

In some embodiments (not specifically illustrated), a metal layer may be deposited over the recessed gate structures. For example, the metal layer may be a similar material as used in the gate electrodes 114 (e.g., tungsten), such as fluorine-free tungsten, which selectively deposits over the material of the gate electrodes 114 (e.g., tungsten) and becomes part of the gate electrodes 114. The metal layer may be formed by a deposition process such as CVD, ALD, the like, or any suitable method.

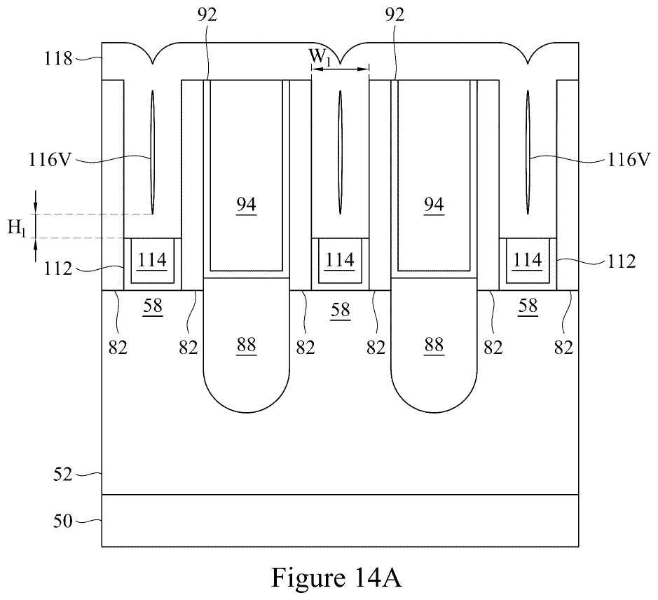

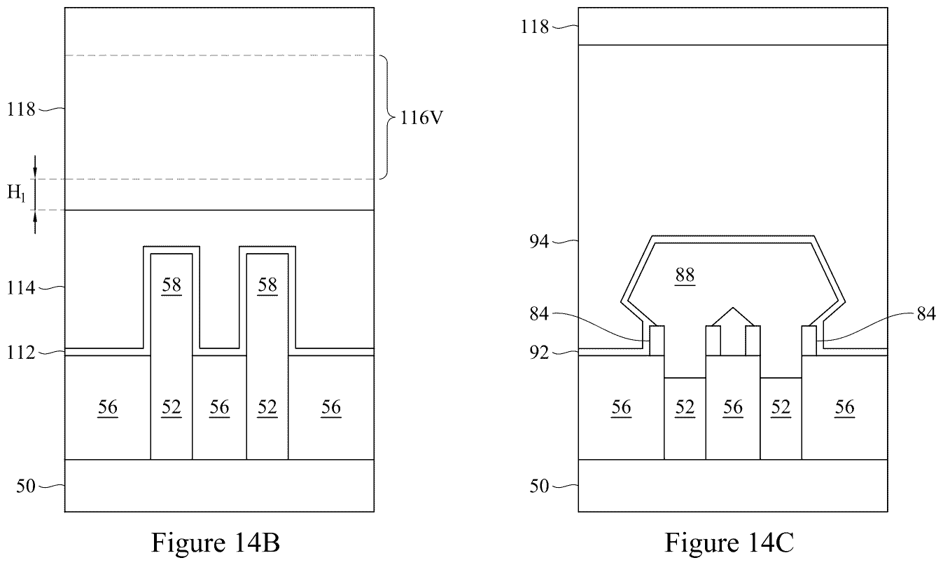

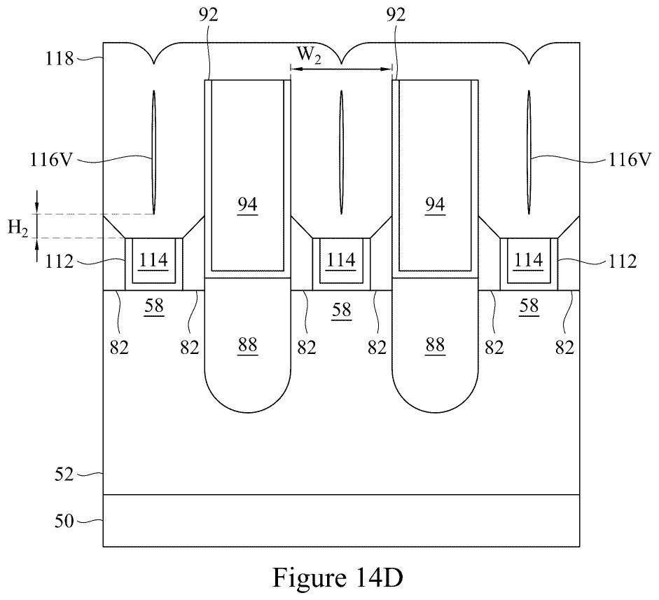

In FIGS. 14A-14D, a dielectric layer 118 is conformally deposited in the recesses 116. FIG. 14A illustrates embodiments forming the dielectric layer 118 over the structure relating to FIG. 13A. The dielectric layer 118 may also be formed on the top surfaces of the gate spacers 82, the first ILD 94, and the CESL 92. In some embodiments, the dielectric layer 118 is formed of one or more dielectric layers comprising dielectric material(s) that have a high etch selectivity from the etching of the first ILD 94 and, optionally, the CESL 92. Acceptable dielectric materials may include silicon nitride, silicon carbonitride, silicon oxynitride, silicon oxycarbonitride, or the like, which may be formed by a conformal deposition process such as chemical vapor deposition (CVD), plasma-enhanced chemical vapor deposition (PECVD), atomic layer deposition (ALD), plasma-enhanced atomic layer deposition (PEALD), FCVD, or the like. Other insulation materials formed by any acceptable process may be used.

In some embodiments, pinch-off occurs during deposition of the dielectric layer 118, such that the formation of the dielectric layer 118 in the recesses 116 is incomplete. As a result, voids 116V are formed from the portions of the recesses 116 that are not filled by the dielectric layer 118. The voids 116V may be seams extending lengthwise through the recesses 116. In some embodiments, each of the illustrated voids 116V may represent a plurality of discrete voids extending lengthwise through the recesses 116. In addition, an upper surface of the dielectric layer 118 may be non-planar, for example, having dips directly above the gate structures. The voids 116V in the dielectric layer 118 may extend starting from a height H₁ above the gate electrodes 114 of the gate structures. For example, the height H₁ may range from 5 nm to 15 nm above the gate structures. In some embodiments where the dielectric layer 118 is conformally deposited in the recesses 116, the height H₁ is about the same as the thickness of the dielectric layer 118 along the sidewalls of the recesses 116, such that the height H₁ is about half of the width W₁.

FIG. 14B illustrates a cross-section along the dielectric layer 118, wherein short-dashed lines indicate uppermost and lowermost edges of the void 116V. Similarly as discussed above, the illustrated void 116V may extend laterally through the dielectric layer 118 or may include a plurality of discrete voids (not specifically illustrated).

FIG. 14D illustrates embodiments forming the dielectric layer 118 over the structure relating to FIG. 13D. Similarly as described above, the voids 116V may form due to incomplete deposition, and the upper surface of the dielectric layer 118 may be non-planar having dips directly above the gate structures. Due to differences in the size and shape of the recesses 116′ in these embodiments as compared to FIG. 14A, the voids 116V may form at a height H₂ above the gate electrodes 114 that is different from the height H₁ in FIG. 14A. For example, the height H₂ may be greater than the height H₁, and the height H₂ may range from 10 nm to 20 nm above the gate structures. In some embodiments, the height H₂ is about the same as the thickness of the dielectric layer 118 along the sidewalls of the recesses 116, such that the height H₂ is about half of the width W₂. Note that FIGS. 14B and 14C may be applicable and analogous to these embodiments, albeit illustrating the height H₂ instead of the height H₁.

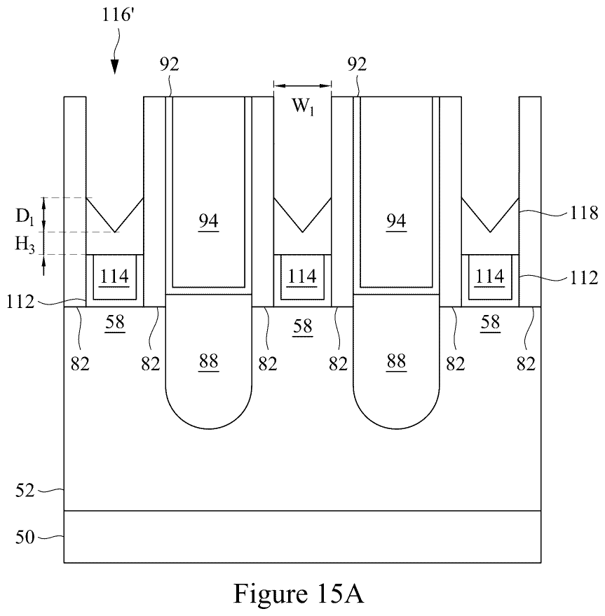

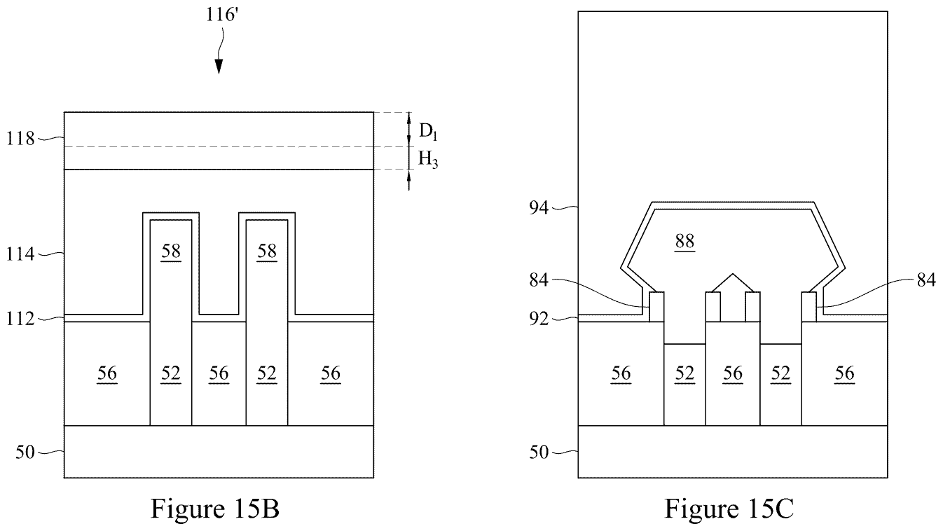

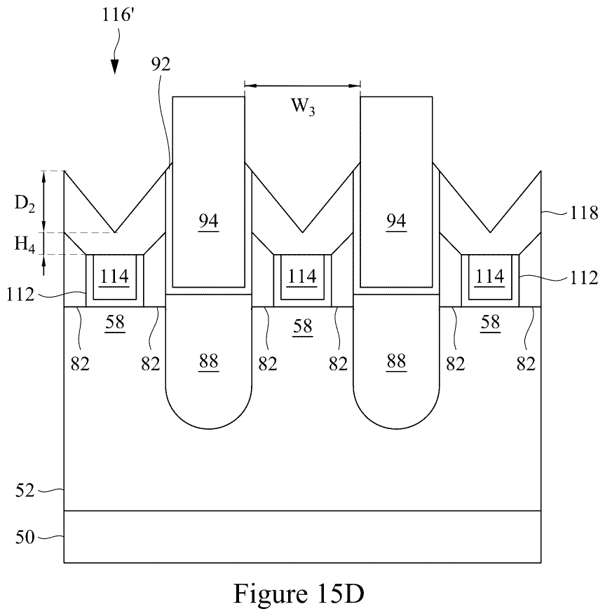

In FIGS. 15A-15D, the dielectric layer 118 is recessed to form (or re-form) recesses 116′ directly above the gate structures, thereby converting the dielectric layer 118 to a dielectric cap. FIG. 15A illustrates embodiments recessing the dielectric layer 118 of the structure relating to FIG. 14A. The dielectric layer 118 may be recessed using any acceptable etching process, such as one that is selective to the material of the dielectric layer 118 (e.g., selectively etches the materials of the dielectric layer 118 at a faster rate than the materials of the first ILD 94, the CESL 92, and the gate spacers 82). The etching process may also remove the excess portions of the dielectric layer 118, which excess portions are over the top surfaces of the gate spacers 82, the first ILD 94, and the CESL 92.

The recessing may be referred to as a deep recessing and will breach the voids 116V. In addition, the recessing may etch the dielectric layer 118 past the voids 116V, effectively removing the voids 116V. For example, a lowermost point of the recess 116′ may have a height H₃ above the gate electrode 114 ranging from 5 nm to 15 nm (e.g., less than the height H₁ of the lowermost point of the void 116V above the gate electrode 114). In addition, an upper surface of the recessed dielectric layer 118 may have a concave, bowl-like, or angular (e.g., triangular) shape, such as a V-shape. For example, the upper surface of the dielectric layer 118 may have a depth D₁ from a topmost point ranging from 5 nm to 20 nm. The depth D₁ along a middle portion of the dielectric layer 118 may be due to a higher etch rate through the voids 116V and less obstruction from the sidewalls of the recesses 116′ as compared to a lower etch rate and more obstruction along the sidewalls of the recesses 116′.

FIG. 15B illustrates a cross-section along the dielectric layer 118, wherein a long-dashed line indicates a lowermost edge of the recess 116′ (e.g., a lowermost edge of the upper surface of the recessed dielectric layer 118). In some embodiments (not specifically illustrated), an uppermost edge and/or the lowermost edge of the upper surface of the dielectric layer 118 may be non-linear. As a result, the depth D₁ may vary along the length of the dielectric layer 118.

FIG. 15D illustrates embodiments recessing the dielectric layer 118 of the structure relating to FIG. 14D. The recessing may be performed similarly as described above. The etching process performed on the dielectric layer 118 may have a lower etch selectivity with the gate spacers 82 and the CESL 92 as compared with a higher etch selectivity with the first ILD 94. In some embodiments where the CESL 92 is made of a same material as the dielectric layer 118 (e.g., silicon nitride), the etching process may have no appreciable etch selectivity between the CESL 92 and the dielectric layer 118. As a result, the CESL 92 may also be recessed below a top surface of the first ILD 94. As illustrated, the recessing will etch the dielectric layer 118 past the voids 116V, effectively removing the voids 116V. For example, a lowermost point of the recess 116′ may have a height H₄ above the gate electrode 114 ranging from 5 nm to 15 nm (e.g., less than the height H₂ of the lowermost point of the void 116V above the gate electrode 114). In addition, an upper surface of the recessed dielectric layer 118 may have a concave, bowl-like, or angular (e.g., triangular) shape, such as a V-shape. For example, the upper surface of the dielectric layer 118 may have a depth D₂ from a topmost point ranging from 5 nm to 20 nm. The depth D₂ along a middle portion of the dielectric layer 118 may be due to a higher etch rate through the voids 116V and less obstruction from the sidewalls of the recesses 116′ as compared to a lower etch rate and more obstruction along the sidewalls of the recesses 116′. Note that FIGS. 15B and 15C may be applicable and analogous to these embodiments, albeit illustrating depth D₂ and height H₄ instead of depth D₁ and height H₃, respectively.

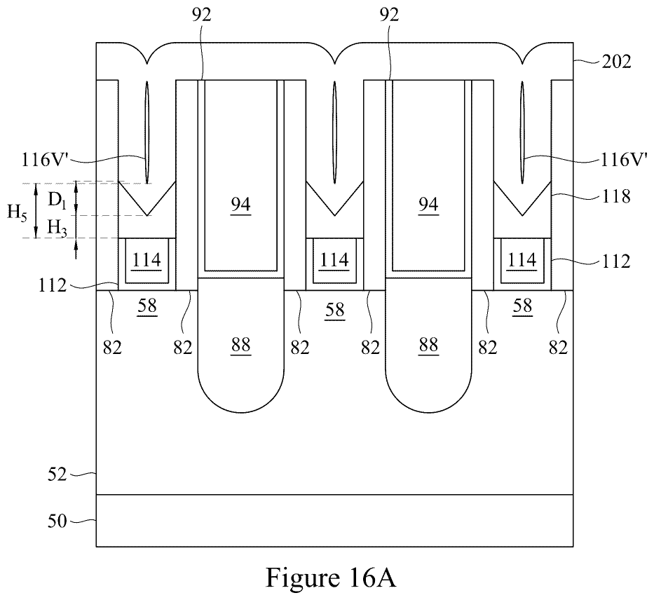

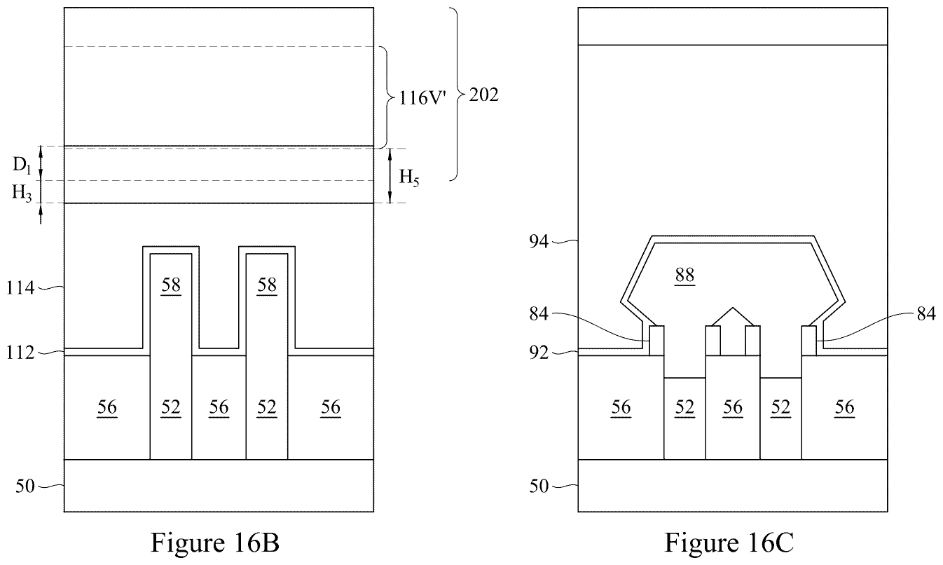

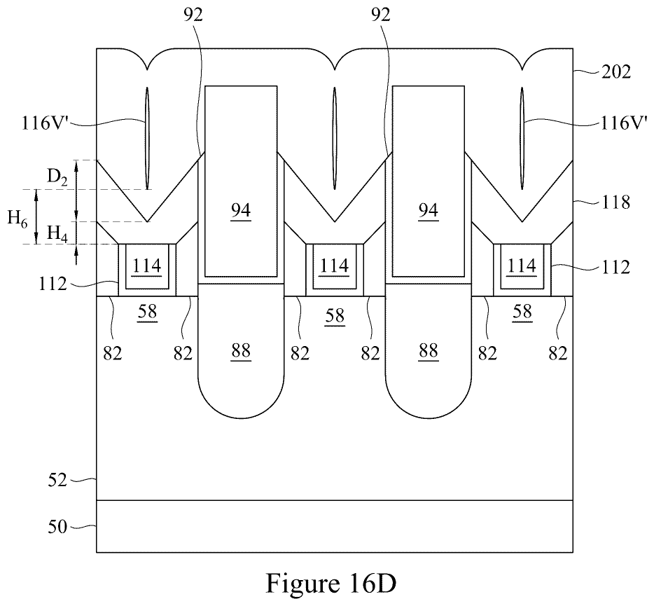

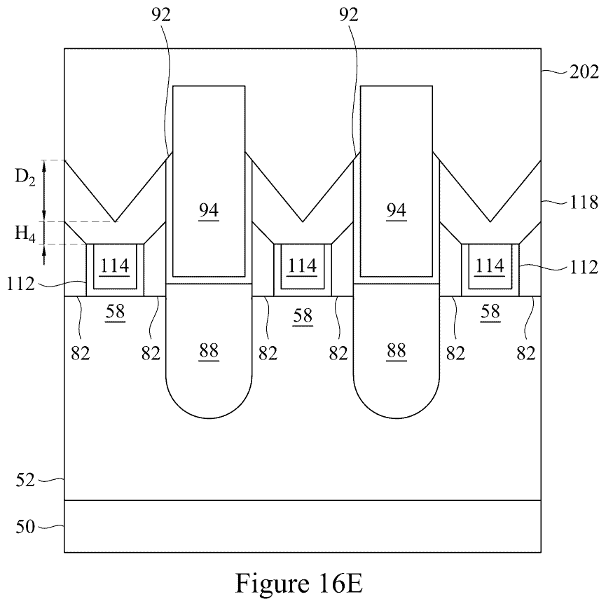

In FIGS. 16A-16E, a semiconductor layer 202 is conformally deposited in the recesses 116′. The semiconductor layer 202 may also be formed on the top surfaces of the dielectric layer 118, the first ILD 94, and the CESL 92. In some embodiments, the semiconductor layer 202 is formed of a semiconductor material that has a very high etch selectivity from the etching of the first ILD 94 and, optionally, the CESL 92. In particular, the etch selectivity of the semiconductor layer 202 with the first ILD 94 is greater than the etch selectivity of the dielectric layer 118 with the first ILD 94. Acceptable semiconductor materials may include silicon, silicon-germanium, silicon boride, or the like. For example, the semiconductor layer 202 may be formed by a conformal deposition process such as low pressure chemical vapor deposition (LPCVD), plasma-enhanced chemical vapor deposition (PECVD), flowable CVD (FCVD), thermal atomic layer deposition (ALD), plasma enhanced atomic layer deposition (PEALD), or the like. The deposition may be performed at temperatures ranging from 250° C. to 550° C. and use precursor materials, such as silane (SiH₄), disilane (Si₂H₆), trisilane (Si₃H₈), dichlorosilane (SiH₂Cl₂), diiodosilane (SiH₂I₂), germane (GeH₄), the like, or a combination thereof. The semiconductor layer 202 may be deposited to a thickness ranging from 10 nm to 50 nm.

In accordance with some embodiments, the semiconductor layer 202 may be formed to have a concentration of hydrogen ranging from 0.5 atomic % to 15 atomic % and a concentration of other elements, such as the semiconductor element(s) (e.g., silicon and/or germanium), ranging from 85 at. % to 99.5 at. %. A hydrogen concentration less than or equal to 15% ensures the semiconductor layer 202 has a high or very high etch selectivity with other features (e.g., the gate spacers 82, the CESL 92, and the first ILD 94). In addition, the semiconductor layer 202 may be formed to have a hydrogen concentration greater than or equal to 0.5% using temperatures less than or equal to 550° C. in order to prevent damage to the gate structures (e.g., the gate electrode 114 and the gate dielectrics 112).

The deposition of the semiconductor layer 202 may be referred to as a deep-recessed deposition because the semiconductor layer 202 is deposited along the bottom of the recesses 116′ re-formed after the deep recessing of the dielectric layer 118 as described above. Similarly as described above regarding deposition of the dielectric layer 118, in some embodiments, pinch-off occurs during deposition of the semiconductor layer 202 (e.g., LPCVD, PECVD, or the like), such that the formation of the semiconductor layer 202 in the recesses 116′ is incomplete. As a result, voids 116V′ may form from the portions of the recesses 116′ that are not filled by the semiconductor layer 202. The voids 116V′ may be seams extending lengthwise through the recesses 116′. In some embodiments, each of the illustrated voids 116V′ may represent a plurality of discrete voids extending lengthwise through the recesses 116′. In addition, an upper surface of the semiconductor layer 202 may be non-planar, for example, having dips directly above the gate structures. In some embodiments, the semiconductor layer 202 is formed using, for example, an FCVD process to fill the recesses 116′, thereby precluding formation of the voids 116V′.

FIG. 16A illustrates embodiments in which the semiconductor layer 202 is formed over the structure relating to FIG. 15A. In accordance with some embodiments, the voids 116V′ in the semiconductor layer 202 may extend above the gate structures starting from a height H₅ above the gate electrodes 114. The height H₅ is greater than the height H₁ (see FIG. 14A) and the height H₃ (see FIG. 15A) because portions of the dielectric layer 118 remain along the bottom of the recesses 116′. For example, the height H₅ may range from 15 nm to 25 nm above the gate structures. Although illustrated with the height H₅ being less than the depth D₁ and the height H₃ combined, in some embodiments, the height H₅ may be greater than the depth D₁ and the height H₃ combined.

FIG. 16B illustrates a cross-section along the gate electrode 114, wherein a long-dashed line indicates a lowermost edge of the semiconductor layer 202. In addition, short-dashed lines indicate uppermost and lowermost edges of the void 116V′. As discussed above, the illustrated void 116V′ may extend laterally through the semiconductor layer 202 or may include a plurality of discrete voids (not specifically illustrated).

FIG. 16D illustrates embodiments in which the semiconductor layer 202 is formed over the structure relating to FIG. 15D. Similarly as described above, the voids 116V′ may form due to incomplete deposition, and the upper surface of the semiconductor layer 202 may be non-planar having dips directly above the gate structures. Due to differences in the size and shape of the recesses 116′ in these embodiments as compared to FIG. 16A, the voids 116V′ may form at a height H₆ above the gate electrodes 114. The height H₆ is greater than the height H₂ (see FIG. 14D) and the height H₄ (see FIG. 15D) because portions of the dielectric layer 118 remain along the bottom of the recesses 116′. For example, the height H₆ may range from 20 nm to 30 nm above the gate structures. Although illustrated with the height H₆ being less than the depth D₂ and the height H₄ combined, in some embodiments, the height H₆ may be greater than the depth D₂ and the height H₄ combined. Note that FIGS. 16B and 16C may be applicable and analogous to these embodiments, albeit illustrating heights H₄ and H₆ instead of heights H₃ and H₅.

FIG. 16E illustrates embodiments in which the semiconductor layer 202 is formed over the structure relating to FIG. 15D using, for example, an FCVD process or any suitable gap-fill deposition process that will fill the recesses 116′ completely. As a result of a complete filling of the recesses 116′, the voids 116V′ will not form therein. Further, the upper surface of the semiconductor layer 202 may be planar (within process variations). Although not specifically illustrated, note that the embodiment of FIG. 16A may also include forming the semiconductor layer 202 using an FCVD process, similarly resulting in a complete fill of the recesses 116′, no voids 116V′, and a substantially planar upper surface. Note that FIGS. 16B and 16C may be applicable and analogous to these embodiments, albeit illustrating height H₄ instead of height H₃ and excluding the void 116V′. In addition, subsequent method steps, discussion, and figures may be applicable to these embodiments relating to FIG. 16E, albeit excluding the voids 116V′.

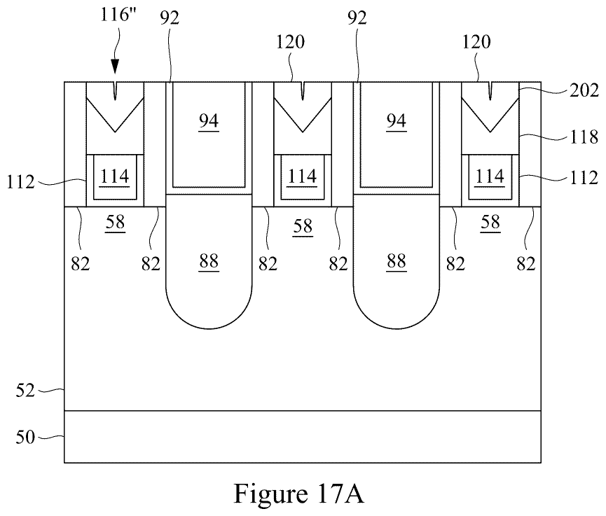

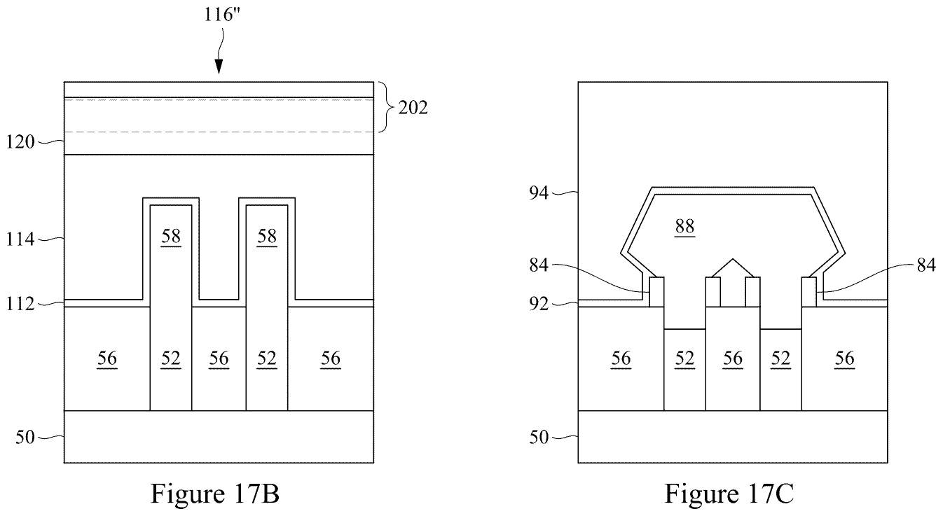

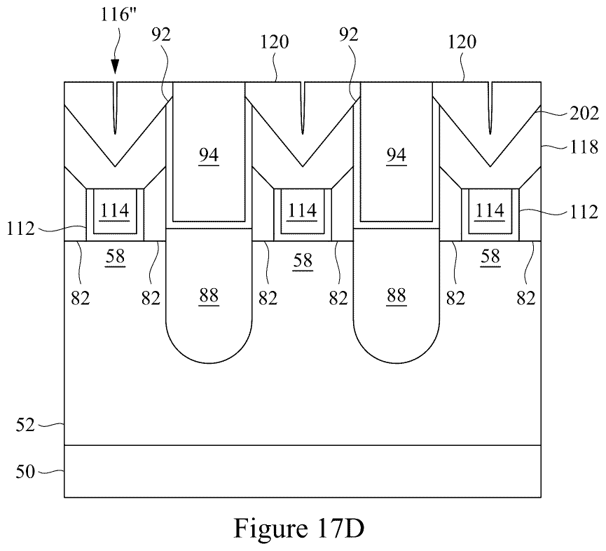

In FIGS. 17A-17D, a removal process is performed to remove the excess portions of the semiconductor layer 202, which excess portions are over the top surfaces of the gate spacers 82, the first ILD 94, and the CESL 92, thereby forming gate masks 120 (e.g., hybrid structures comprising remaining portions of the dielectric layer 118 and the semiconductor layer 202). FIG. 17A illustrates embodiments in which the removal process is performed on the structure relating to FIG. 16A. In some embodiments, a planarization process such as a CMP, an etch-back process, combinations thereof, or the like may be utilized. The dielectric layer 118 and the semiconductor layer 202, when planarized, have portions left in the recesses 116′ (thus forming the gate masks 120). After the planarization process, the top surfaces of the gate spacers 82, the CESL 92, the first ILD 94, and the gate masks 120 are coplanar (within process variations). Gate contacts will be subsequently formed to penetrate through the gate masks 120 to contact the top surfaces of the gate electrodes 114. The voids 116V′ (if present) may be breached by the planarization process thereby forming recesses 116″ in the semiconductor layer 202. In some embodiments (not specifically illustrated), the removal process may continue past the voids 116V′, effectively removing the voids 116V′ and not forming the recesses 116″. In embodiments in which an FCVD (or similar) process was used to form the semiconductor layer 202, the gate mask 120 will not include the voids 116V′ regardless of the extent to which the removal process is performed. Portions of the gate spacers 82 may be removed, and remaining portions of the gate spacers 82 may be disposed on sidewalls of the gate masks 120 and the gate structures (including the gate dielectrics 112 and the gate electrodes 114). The removal process may stop short of reaching the dielectric layer 118.

FIG. 17B illustrates a cross-section along the gate electrode 114, wherein a long-dashed line indicates the lowermost edge of the semiconductor layer 202, and a long-dashed line indicates a lowermost edge of the recess 116″ (e.g., formerly the lowermost edge of the void 116V′).

FIG. 17D illustrates embodiments in which the removal process is performed on the structure relating to FIG. 16D. Similarly as described above, the voids 116V″ may be breached, thereby forming the recesses 116″. In some embodiments (not specifically illustrated), the removal process may continue past the voids 116V′, effectively removing the voids 116V′ and not forming the recesses 116″. The removal process may stop short of reaching the CESL 92, the gate spacers 82, and the dielectric layer 118. Note that FIGS. 17B and 17C may be applicable and analogous to these embodiments.

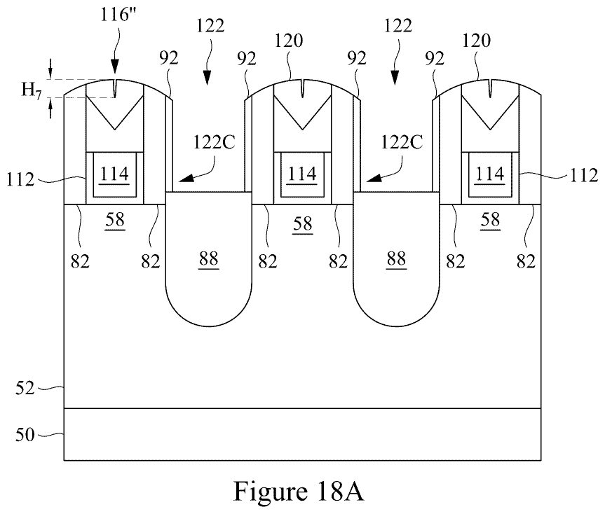

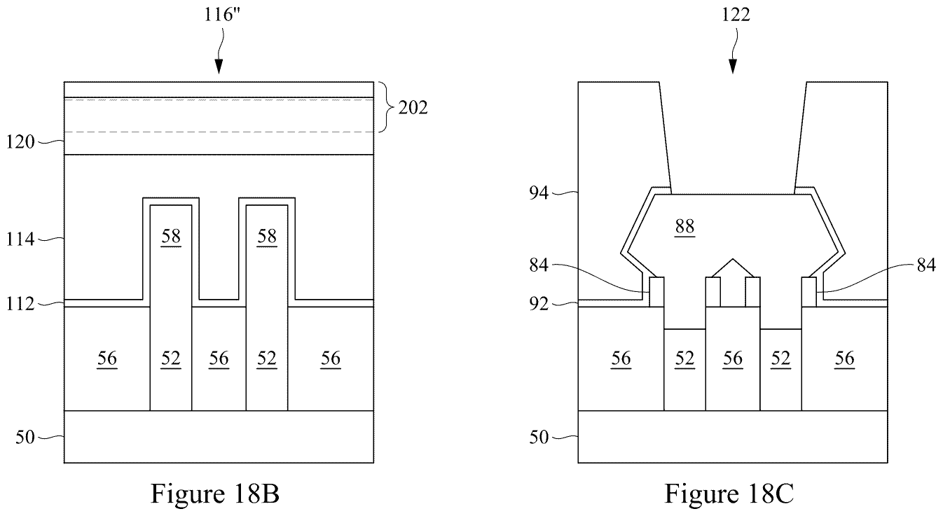

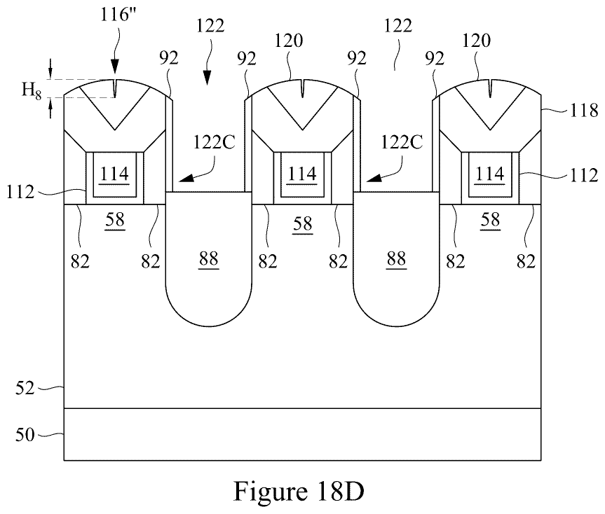

In FIGS. 18A-18D, contact openings 122 are formed through the first ILD 94 and the CESL 92. FIG. 18A illustrates embodiments in which the contact openings 122 are formed in the structure relating to FIG. 17A. The contact openings 122 are source/drain contact openings formed by a self-aligned contact (SAC) process so that substantially no residue of the first ILD 94 remains in corner regions 122C of the contact openings 122. The corner regions 122C of the contact openings 122 are the corners defined by the sidewalls of the CESL 92 and the top surfaces of the epitaxial source/drain regions 88.

As an example to form the contact openings 122, a mask (not specifically illustrated) may be formed over the first ILD 94 and the gate masks 120. The mask is patterned with slot openings corresponding to the contact openings 122. The mask may be, e.g., a photoresist, such as a single layer photoresist, a bi-layer photoresist, a tri-layer photoresist, or the like, which may be patterned using acceptable photolithography techniques to form the slot openings. Other types of masks formed by any acceptable process may be used. The slot openings are strips that run parallel to the lengthwise directions of the fins 52, overlapping the first ILD 94 and the gate masks 120. A combination of the slot openings and the above-described etch selectivities (e.g., etching the material of the first ILD 94 at a faster rate than the other materials) allows for small contact openings 122 to be formed more easily, thereby avoiding any necessity (e.g., difficulty) of forming similarly small openings in the mask.

The first ILD 94 may then be etched using the mask as an etching mask and using the CESL 92 as an etch stop layer. In addition, the gate masks 120 serve as etching masks for the gate structures not covered by the above-described mask (e.g., the photoresist). The etching may be any acceptable etching process, such as one that is selective to the material of the first ILD 94. For example, the etching process selectively etches the material of the first ILD 94 at a faster rate than the material(s) of the CESL 92, the gate spacers 82, and the gate masks 120 (e.g., the semiconductor layer 202). The etching process may be anisotropic. The portions of the first ILD 94 uncovered by the mask (e.g., exposed by the slot openings) are thus etched to form the contact openings 122. The contact openings 122 are then extended through the CESL 92 by any acceptable etching process to expose the epitaxial source/drain regions 88. After the etching processes, the mask may be removed, such as by any acceptable ashing process. Depending on the selectivity of the etching processes used to form the contact openings 122, some losses of the CESL 92, the gate spacers 82, and/or the gate masks 120 may occur. As a result, the sidewalls and/or top surfaces of the CESL 92, the gate spacers 82, and/or the gate masks 120 may have a convex or downward curved shape after etching. The gate masks 120 cover the gate structures (including the gate dielectrics 112 and the gate electrodes 114) during etching, thereby protecting the gate structures from etching losses.

As discussed above, in accordance with some embodiments, the material of the first ILD 94 has a high etch selectivity with the materials of the gate spacers 82 and the CESL 92. In addition, the material of the first ILD 94 has a greater etch selectivity (e.g., a very high etch selectivity) with the exposed material of the gate masks 120 (e.g., the semiconductor layer 202). As a result, etchants will etch the gate spacers 82 and the CESL 92 at a lower rate than the first ILD 94 yet at a faster rate than the semiconductor layer 202, thereby resulting in the top surface having a convex or downward curved shape discussed above. Note that the etchants would etch the material of the dielectric layer 118 at a faster rate than the material of the semiconductor layer 202. As such, the faster rate of etching the dielectric layer 118 is prevented by the semiconductor layer 202 covering the dielectric layer 118. For example, an uppermost point of the top surface (e.g., along the gate mask 120) may extend a height H₇ higher than a lowermost point of the top surface along the gate spacers 82. The height H₇ may range from 5 nm to 20 nm. Further, some of the recesses 116″ may remain in the gate masks 120 due to a minimal amount of the semiconductor layer 202 being etched. Further, the recesses 116″ (if present) may remain in the gate masks 120 also due to the gate masks 120 being etched by little to no amount.

FIG. 18D illustrates embodiments in which the etching process is performed on the structure relating to FIG. 17D. Similarly as described above, the sidewalls and/or top surfaces of the CESL 92 and the gate masks 120 may have a convex or downward curved shape after etching. For example, an uppermost point of the top surface (e.g., along the gate mask 120) may extend a height H₈ higher than a lowermost point of the top surface along the gate spacers 82. The height H₈ may range from 5 nm to 20 nm. In some embodiments, the gate masks 120 may remain substantially flat due to the first ILD 94 having a very high etch selectivity with the semiconductor layer 202 of the gate masks 120. Further, the recesses 116″ (if present) may remain in the gate masks 120 also due to the gate masks being etched by little to no amount. Note that FIGS. 18B and 18C may be applicable and analogous to these embodiments, albeit illustrating a different geometry of the various layers, as described above.

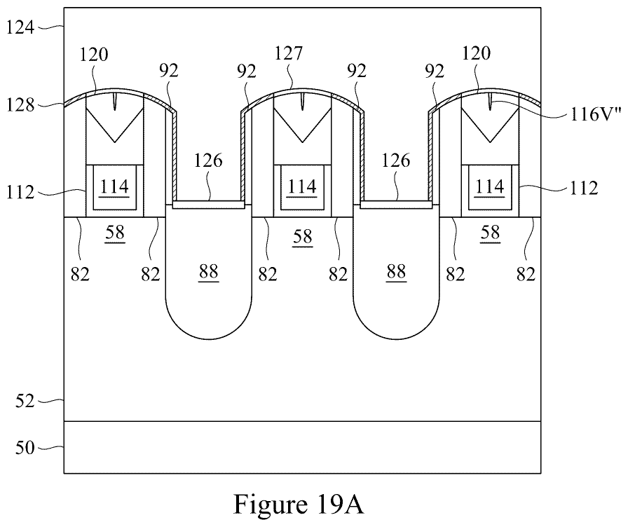

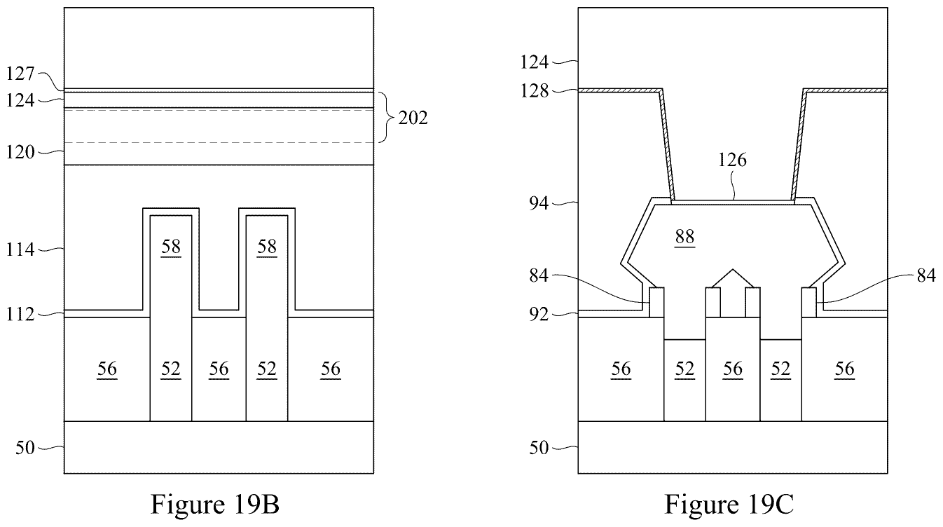

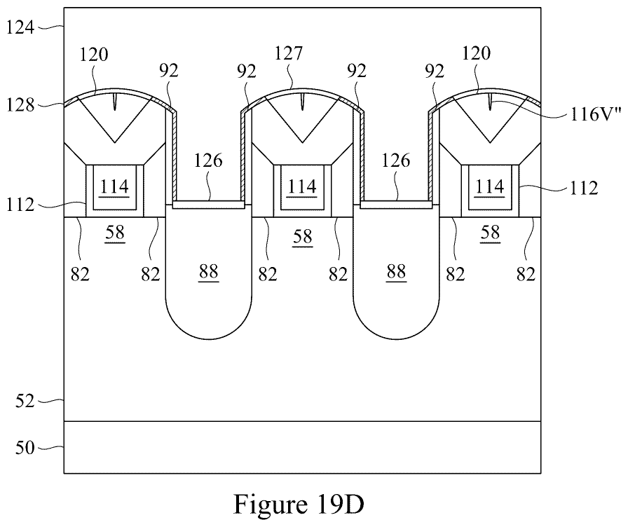

In FIGS. 19A-19D, a conductive layer 124 for source/drain contacts is formed in the contact openings 122. FIG. 19A illustrates embodiments in which the conductive layer 124 is formed over the structure relating to FIG. 18A. For example, the conductive layer 124 may include one or more layers and be formed by forming a liner (not separately illustrated), such as a diffusion barrier layer, an adhesion layer, and/or the like, and a conductive material in the contact openings 122. The liner may include titanium, titanium nitride, tantalum, tantalum nitride, or the like. The conductive material may be a metal such as copper, a copper alloy, silver, gold, tungsten, cobalt, aluminum, nickel, or the like, which may be formed by a deposition process such as PVD, ALD, CVD, or the like. The conductive layer 124 is formed on the sidewalls and/or top surfaces of the gate spacers 82, the CESL 92, and/or the gate masks 120.

Optionally, metal-semiconductor alloy regions are formed between the conductive layer 124 and certain underlying features. For example, source/drain alloy regions 126 are formed between the epitaxial source/drain regions 88 and the conductive layer 124. The source/drain alloy regions 126 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The source/drain alloy regions 126 can be formed by depositing a metal 128 in the contact openings 122 (e.g., on the epitaxial source/drain regions 88), and performing a thermal anneal process. As a result, the source/drain alloy regions 126 are formed between portions of the metal 128 in physical contact with the epitaxial source/drain regions 88 during the thermal anneal process.

In addition, other metal-semiconductor alloy regions may be formed similarly as described above. For example, gate mask alloy regions 127 may be formed between the semiconductor layer 202 (e.g., the gate mask 120) and the conductive layer 124. Similarly as the source/drain alloy regions 126, the gate mask alloy regions 127 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The gate mask alloy regions 127 can be formed by the metal 128 also depositing over the gate masks 120, and performing the thermal anneal process discussed above. As a result, the gate mask alloy regions 127 are formed between portions of the metal 128 being in physical contact with the semiconductor layer 202 of the gate masks 120 during the thermal anneal process.

For example, the source/drain alloy regions 126 and the gate mask alloy regions 127 may both be silicide regions, both be germanide regions, or both be silicon-germanide regions, having similar or different compositions from one another. In some embodiments, the source/drain alloy regions 126 may be germanide regions or silicon-germanide regions, while the gate mask alloy regions 127 are silicide regions. Moreover, in some embodiments, the source/drain alloy regions 126 may be silicide regions, while the gate mask alloy regions 127 are germanide regions or silicon-germanide regions.

In accordance with some embodiments, the metal 128 is deposited on the sidewalls and top surfaces of the gate spacers 82, the CESL 92, and the gate masks 120. The metal 128 can be any metal capable of reacting with the semiconductor materials (e.g., silicon, silicon-germanium, germanium, etc.) of the epitaxial source/drain regions 88 (and of the semiconductor layer 202) to form a low-resistance metal-semiconductor alloy, such as nickel, cobalt, titanium, tantalum, platinum, tungsten, other noble metals, other refractory metals, rare earth metals or their alloys. The metal 128 can be deposited by a deposition process such as ALD, CVD, PVD, or the like. After the thermal anneal process, a cleaning process, such as a wet clean, may optionally be performed to remove any residual of the metal 128 from the contact openings 122, such as from surfaces of the metal-semiconductor alloy regions 126. In the illustrated embodiment, the cleaning process is omitted so that residue of the metal 128 remains on the sidewalls of the CESL 92. The conductive layer 124 can then be formed on the metal-semiconductor alloy regions 126 and the residual of the metal 128 (if present), as illustrated.

In embodiments in which the recesses 116″ are present in the gate masks 120 as discussed above, the deposition of the metal 128 and the conductive layer 124 over the gate structures may form voids 116V″. The metal 128 may partially fill upper portions of the recesses 116″, thereby leaving the voids 116V″ at the bottom. After the thermal anneal process discussed above, those portions in the recesses 116″ may also become part of the gate mask alloy regions 126B. In some embodiments (not specifically illustrated), the metal 128 and/or the gate mask alloy region 126B may fill all or substantially all of the recesses 116″, thereby not forming the voids 116V″.

FIG. 19D illustrates embodiments in which the conductive layer 124 and, optionally, the metal-semiconductor alloy regions 126 are formed over the structure relating to FIG. 18D. Similarly as described above, source/drain alloy regions 126A may be formed along the epitaxial source/drain regions 88, and the gate mask alloy regions 126B may be formed along the gate masks 120 (e.g., the semiconductor layer 202). In addition, the voids 116V″ may be formed in the recesses 116″, and portions of the metal 128 deposited in the recesses 116″ may also become part of the gate mask alloy regions 126B. Further, the conductive layer 124 may be formed over the metal 128. In some embodiments (not specifically illustrated), the metal 128 and/or the gate mask alloy region 126B may fill all or substantially all of the recesses 116″, thereby not forming the voids 116V″. Note that FIGS. 19B and 19C may be applicable and analogous to these embodiments, albeit illustrating a different geometry of the various layers, as described above.

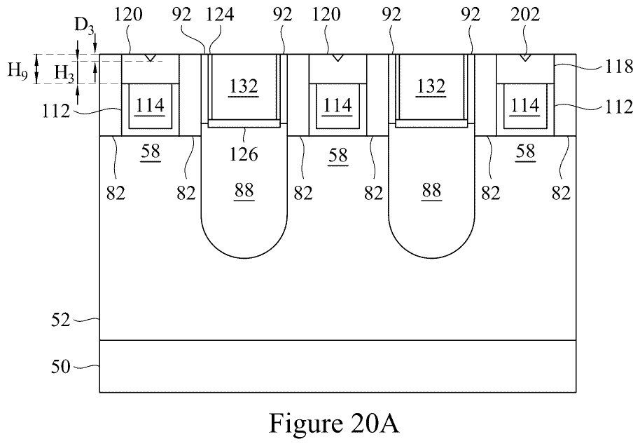

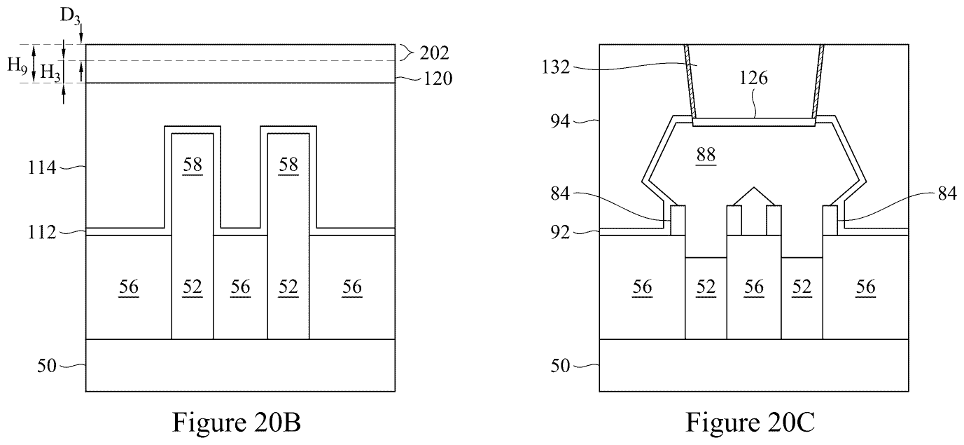

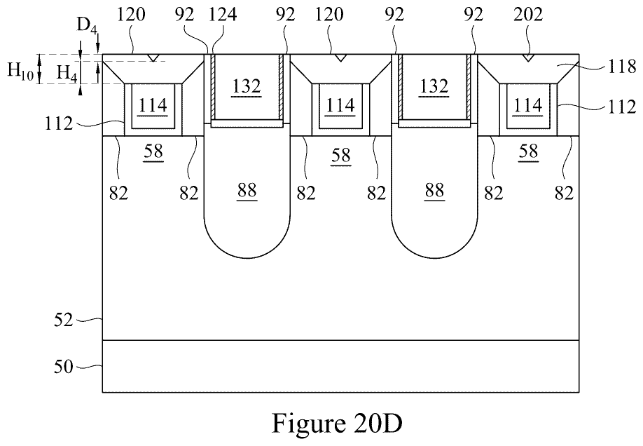

In FIGS. 20A-20D, a removal process is performed to remove excess portions of the metal 128 (if present) and the conductive layer 124, which excess portions are over the top surfaces of the gate spacers 82, the CESL 92, the first ILD 94, and the gate masks 120. FIG. 20A illustrates embodiments in which the removal process is performed on the structure relating to FIG. 19A. The removal process may also remove the gate mask alloy regions 126B (if present) and some portions of the gate spacers 82, the CESL 92, the first ILD 94, and/or the gate masks 120. In some embodiments, a planarization process such as a CMP, an etch-back process, combinations thereof, or the like may be utilized. The remaining conductive layer 124 in the contact openings 122 form lower source/drain contacts 132 in the contact openings 122. After the planarization process, the top surfaces of the gate spacers 82, the CESL 92, the first ILD 94, the gate masks 120, the metal 128 (if present), and the lower source/drain contacts 132 are coplanar (within process variations). The lower source/drain contacts 132 extend through the first ILD 94.

In accordance with some embodiments, the removal process removes enough of the gate masks 120 to breach and remove the voids 116V″ (if present). As illustrated, following the removal process, the gate masks 120 may include the dielectric layer 118 along the gate structures and sidewalls of the gate spacers 82. The gate masks 120 may further include portions of the semiconductor layer 202 embedded within the dielectric layer 118. For example, the gate masks 120 may have a height H₉ above the gate structures ranging from 40 nm to 80 nm, and the semiconductor layer 202 may extend into the dielectric layer 118 to a depth D₃ ranging from 35 nm to 75 nm. As such, the height H₉ may be a sum of the height H₃ and the depth D₃. In some embodiments (not specifically illustrated), the removal process may remove an entirety of the semiconductor layer 202.

A benefit of the semiconductor layer 202 is realized in embodiments in which the height H₉ is greater than the height H₁ of the voids 116V above the gate structures after formation of the dielectric layer 118 (see FIG. 14A). In particular, formation of the semiconductor layer 202 over the recessed dielectric layer 118 ensures that no portions of voids (e.g., the voids 116V, the voids 116V′, or the voids 116V″) or recesses (e.g., the recesses 116, the recesses 116′, or the recesses 116″) remain in the gate masks 120 after this removal process. Subsequent etching of the gate masks 120 may be performed with improved control due to the gate masks 120 being substantially voidless and seamless. Further, the small amount of the semiconductor layer 202 remaining (if any) ensures that the semiconductor layer 202 contributes minimal to zero parasitic capacitance during use of the semiconductor device. In particular, the gate mask 120 will have an effective dielectric constant based mostly on the lower dielectric constant of the dielectric layer 118 as compared to the higher dielectric constant of the semiconductor layer 202.

FIG. 20D illustrates embodiments in which the removal process is performed on the structure relating to FIG. 19D. Similarly as described above, the removal process removes excess portions of the metal 128 (if present) and the conductive layer 124. In addition, the removal process may remove the gate mask alloy regions 126B (if present) and some portions of the CESL 92, the first ILD 94, and/or the gate masks 120. The removal process removes enough of the gate masks 120 to breach and remove the voids 116V″ (if present). As illustrated, remaining portions of the gate masks 120 include the dielectric layer 118 along the gate structures and the gate spacers 82. The gate masks 120 may further include portions of the semiconductor layer 202 embedded within the dielectric layer 118. For example, the gate masks 120 may have a height H₁₀ above the gate structures ranging from 40 nm to 80 nm, and the semiconductor layer 202 may extend into the dielectric layer 118 to a depth D₄ ranging from 35 nm to 75 nm. As such, the height H₁₀ may be a sum of the height H₄ and the depth D₄. In some embodiments (not specifically illustrated), the removal process may remove an entirety of the semiconductor layer 202. Similarly as discussed above, embodiments in which the height H₁₀ is greater than the height H₂ provide additional benefits in that remaining portions of the gate masks 120 are substantially voidless or seamless due to formation of the semiconductor layer 202 (see FIG. 14D). Note that FIGS. 20B and 20C may be applicable and analogous to these embodiments, albeit illustrating heights H₁₀ instead of height H₉.

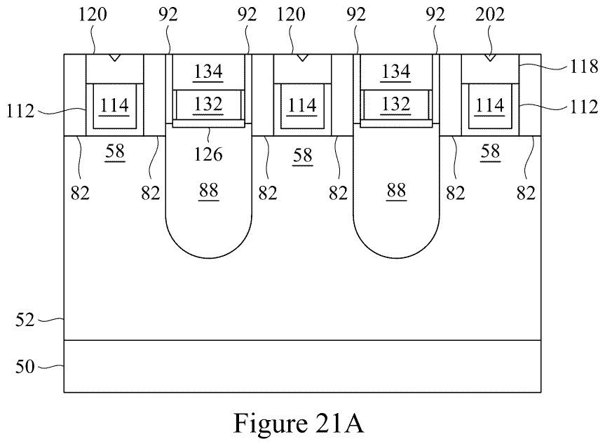

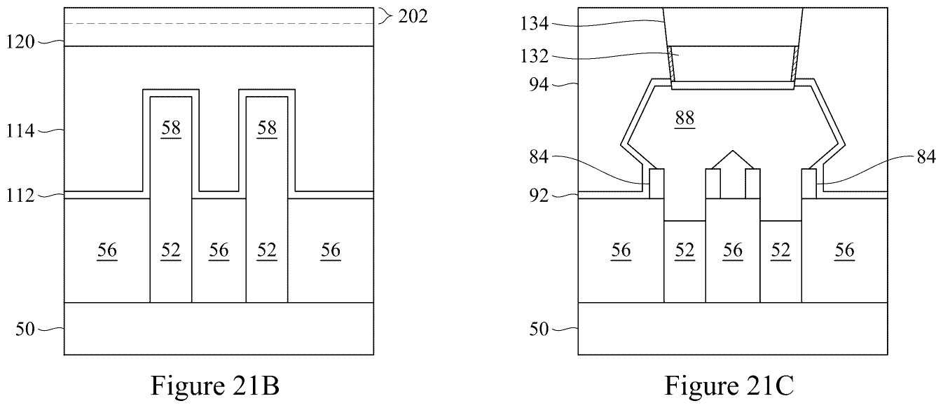

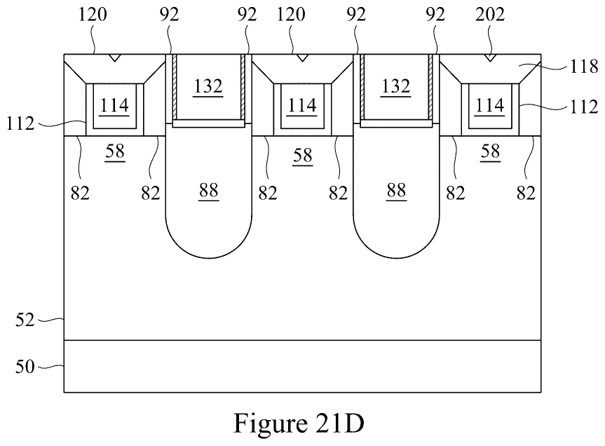

In FIGS. 21A-21D, contact masks 134 are optionally formed over the lower source/drain contacts 132. FIG. 21A illustrates embodiments in which the contact masks 134 are formed over the structure relating to FIG. 20A. The contact masks 134 may be formed of materials that are selected from the same group of candidate materials of the dielectric layer 118 of the gate masks 120. The gate masks 120 (e.g., the dielectric layer 118 or the semiconductor layer 202) and the contact masks 134 may be formed from the same material, or may include different materials. The contact masks 134 may be formed in a similar manner as the gate masks 120. For example, the lower source/drain contacts 132 may be recessed using any acceptable etching process. In some embodiments, exposed portions of the metal 128 (if present) may be recessed with the lower source/drain contacts 132. One or more dielectric layers may be conformally deposited in the recesses. A removal process may be performed to remove the excess portions of the dielectric layer(s), which excess portions are over the top surfaces of the gate spacers 82, the CESL 92, the first ILD 94, and the gate masks 120. In some embodiments, a planarization process such as a CMP, an etch-back process, combinations thereof, or the like may be utilized. The dielectric layer(s), when planarized, have portions left in the recesses (thus forming the contact masks 134). After the planarization process, the top surfaces of the gate spacers 82, the CESL 92, the first ILD 94, the gate masks 120, and the contact masks 134 are coplanar (within process variations). Source/drain contacts and/or gate contacts may be subsequently formed to penetrate through the contact masks 134 to contact the top surfaces of the lower source/drain contacts 132.

FIG. 21D illustrates embodiments in which the contact masks 134 are not formed over the lower source/drain contacts 132 of the structure relating to FIG. 20D. In some embodiments (not specifically illustrated), the contact masks 134 may be formed over some or all of the lower source/drain contacts 132 similarly as described above. Such embodiments are intended to be within the scope of this disclosure, wherein subsequent steps may be performed on any of the embodiments. Note that FIGS. 21B and 21C may be applicable and analogous to these embodiments, albeit illustrating a different geometry of the various layers, as described above.

In accordance with some embodiments relating to FIGS. 21A-21D (not specifically illustrated), the contact masks 134 may be formed over all, some, or none of the lower source/drain contacts 132. For example, the contact masks 134 may be formed over the lower source/drain contacts 132 that will be subsequently connected to source/drain contacts. In addition, the contact masks 134 may not be formed over the lower source/drain contacts 132 that will be subsequently connected to gate contacts. In other embodiments, the contact masks 134 may be formed only over the lower source/drain contacts 132 that will be subsequently connected to the gate contacts.

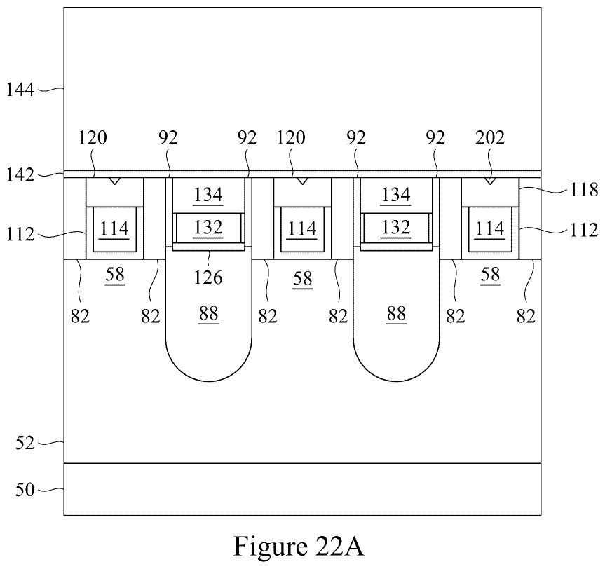

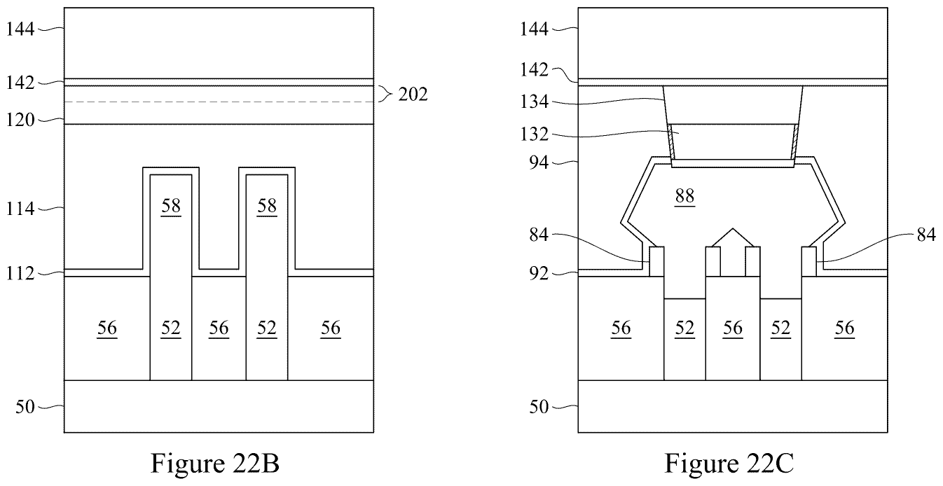

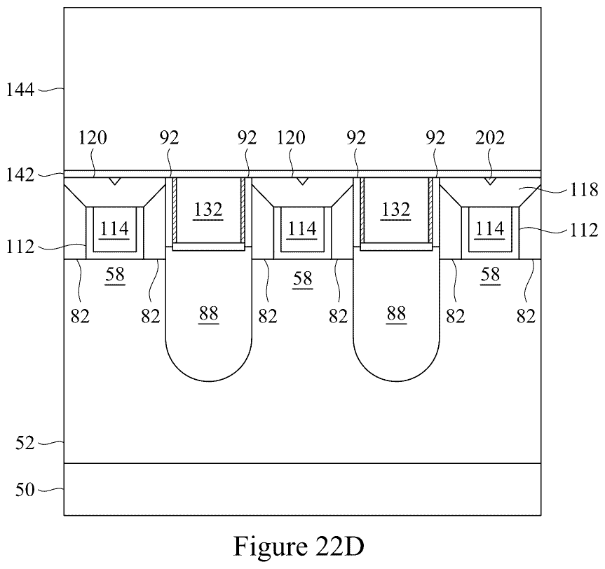

In FIGS. 22A-22D, a second ILD 144 is deposited over the gate spacers 82, the first ILD 94, the gate masks 120 (e.g., the dielectric layer 118 and the semiconductor layer 202, if present), and the contact masks 134 (if present) or the lower source/drain contacts 132. FIG. 22A illustrates embodiments in which the second ILD 144 is formed over the structure relating to FIG. 21A. In some embodiments, the second ILD 144 is deposited as a flowable film, such as being formed by a flowable CVD method. In some embodiments, the second ILD 144 is formed of a dielectric material such as PSG, BSG, BPSG, USG, or the like, which may be deposited by any suitable method, such as CVD, PECVD, or the like.

In some embodiments, an etch stop layer (ESL) 142 is formed between the second ILD 144 and the gate spacers 82, the first ILD 94, the gate masks 120, and the contact masks 134 (if present) or the lower source/drain contacts 132. The ESL 142 may include a dielectric material, such as silicon nitride, silicon oxide, silicon oxynitride, or the like, having a high etch selectivity with the material of the second ILD 144.

FIG. 22D illustrates embodiments in which the ESL 142 and the second ILD 144 are formed over the structure relating to FIG. 21D. Similarly as described above, the ESL 142 may be formed before the second ILD 144, and the ESL 142 may be formed of a dielectric material having a high etch selectivity with the material of the second ILD 144. Note that FIGS. 22B and 22C may be applicable and analogous to these embodiments, albeit illustrating a different geometry of the various layers, as described above.

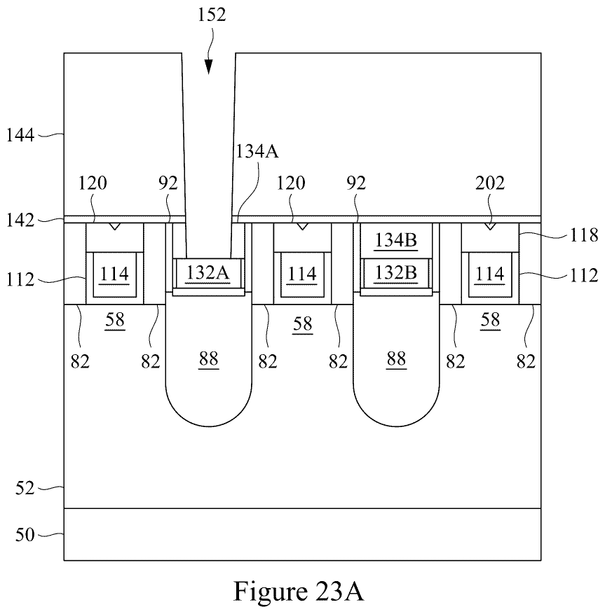

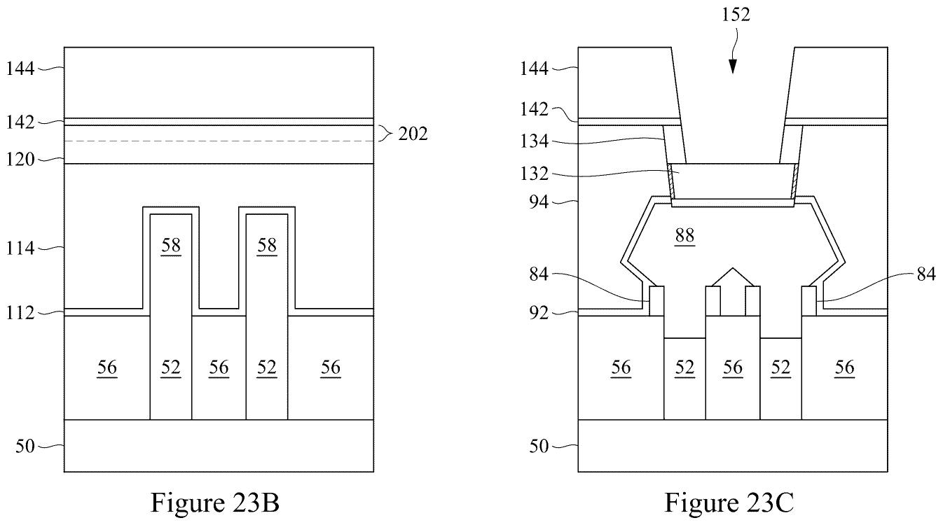

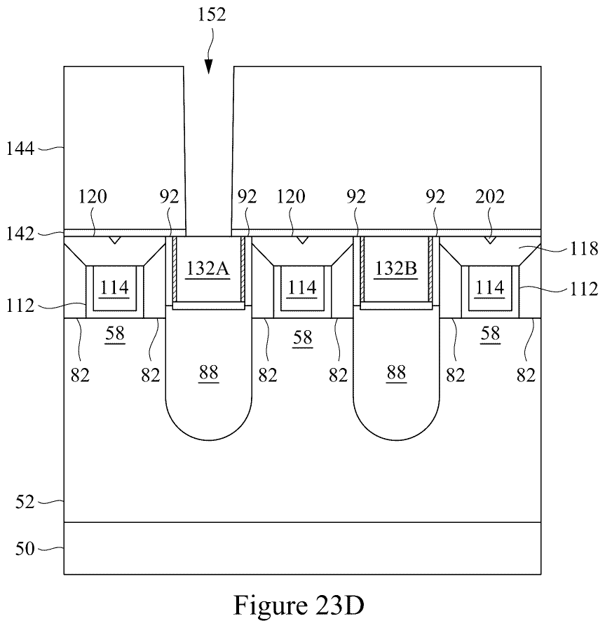

In FIGS. 23A-23D, contact openings 152 are formed through the second ILD 144, the ESL 142, and a first subset of the contact masks 134A (if present) to expose a first subset of the lower source/drain contacts 132A. FIG. 23A illustrates embodiments in which the contact openings 152 are formed in the structure relating to FIG. 22A. The contact openings 152 may be formed using acceptable photolithography and etching techniques. The etching process may be anisotropic. The contact openings 152 expose the top surfaces of the first subset of the lower source/drain contacts 132A. The contact openings 152 may not formed through a second subset of the contact masks 134B (if present), so that the top surfaces of a second subset of the lower source/drain contacts 132B remain covered. The lower source/drain contacts 132A are dedicated to corresponding epitaxial source/drain regions 88 and will not share a gate contact with the gate electrodes 114. The lower source/drain contacts 132B will share a gate contact with a subset of the gate electrodes 114. For example, shared gate contacts may be used for devices in which a gate electrode 114 of a transistor is permanently connected to an epitaxial source/drain region 88 of another transistor, such as used in memory devices (e.g., SRAM cells).

FIG. 23D illustrates embodiments in which the contact openings 152 are formed through the second ILD 144 and the ESL 142 of the structure relating to FIG. 22D. Similarly as described above, the contact openings 152 may be formed to expose the top surfaces of the first subset of the lower source/drain contacts 132A, while a second subset of the lower source/drain contacts 132B remain covered. Although not specifically illustrated, as discussed above, the contact openings 152 may also be formed through the contact masks 134A (if present) to expose the lower source/drain contacts 132A. Note that FIGS. 23B and 23C may be applicable and analogous to these embodiments, albeit illustrating a different geometry of the various layers, as described above.

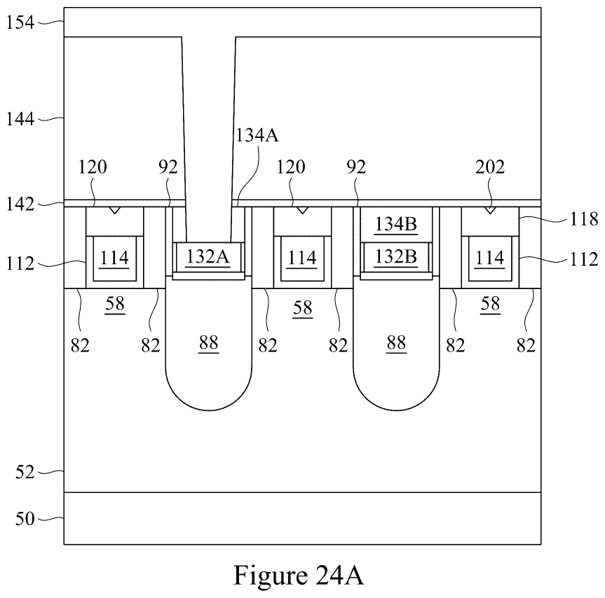

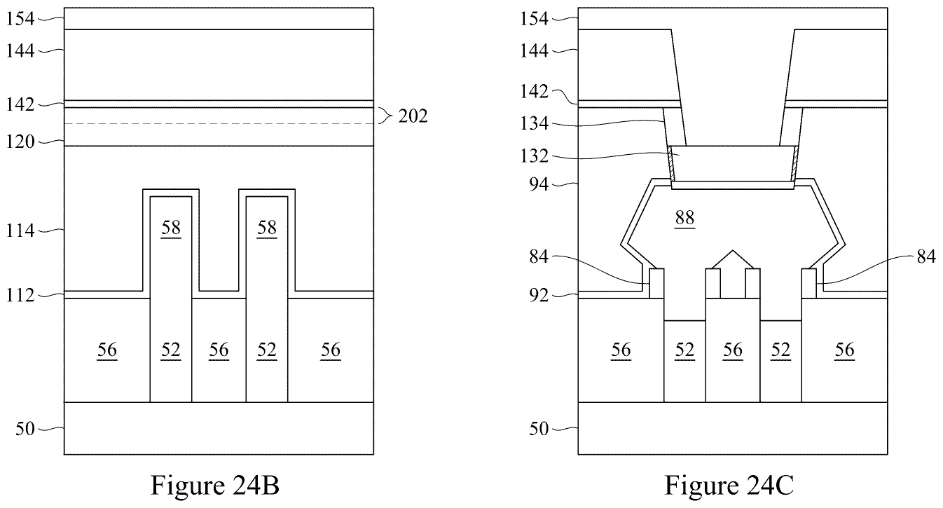

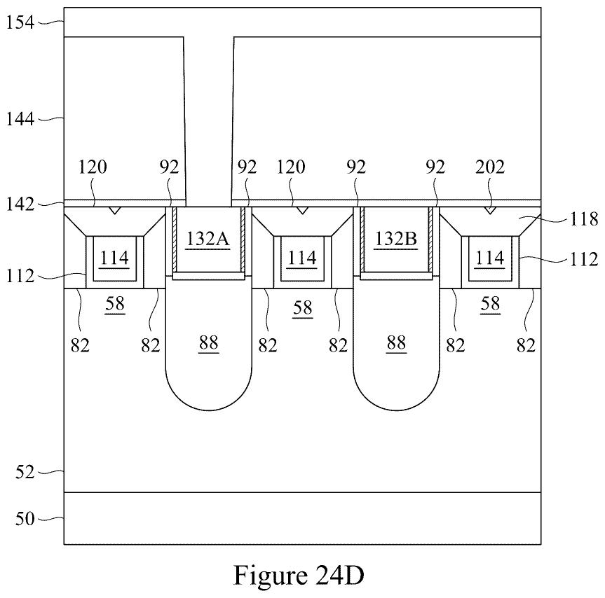

In FIGS. 24A-24D, a conductive layer 154 for gate contacts is formed in the contact openings 152. FIG. 24A illustrates embodiments in which the conductive layer 154 for gate contacts is formed over the structure relating to FIG. 23A. For example, the conductive layer 154 may include one or more layers and be formed by forming a liner (not separately illustrated), such as a diffusion barrier layer, an adhesion layer, and/or the like, and a conductive material in the contact openings 152. The liner may include titanium, titanium nitride, tantalum, tantalum nitride, or the like. The conductive material may be a metal such as copper, a copper alloy, silver, gold, tungsten, cobalt, aluminum, nickel, or the like, which may be formed by a deposition process such as PVD, ALD, CVD, or the like. The conductive layer 154 is formed on the sidewalls and/or top surfaces of the second ILD 144, the ESL 142, the contact masks 134A (if present) and/or the lower source/drain contacts 132A.

FIG. 24D illustrates embodiments in which the conductive layer 154 for gate contacts is formed in the contact openings 152 of the structure relating to FIG. 23D. Similarly as described above, the conductive layer 154 may be formed to extend through the second ILD 144, the ESL 142, and the contact masks 134A (if present) to connect to the lower source/drain contacts 132A. Note that FIGS. 24B and 24C may be applicable and analogous to these embodiments, albeit illustrating a different geometry of the various layers, as described above.

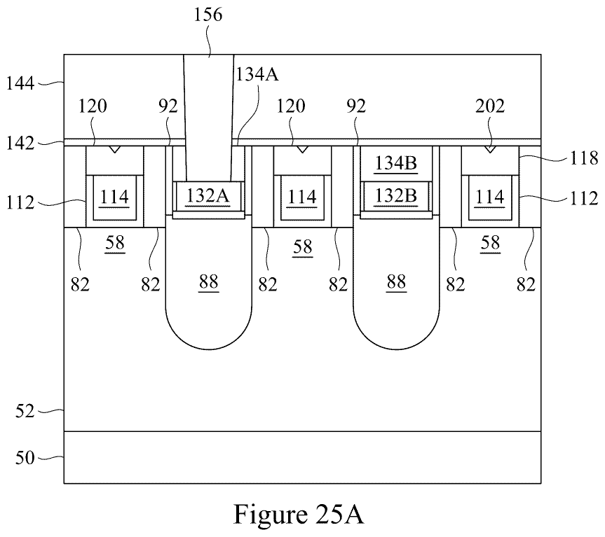

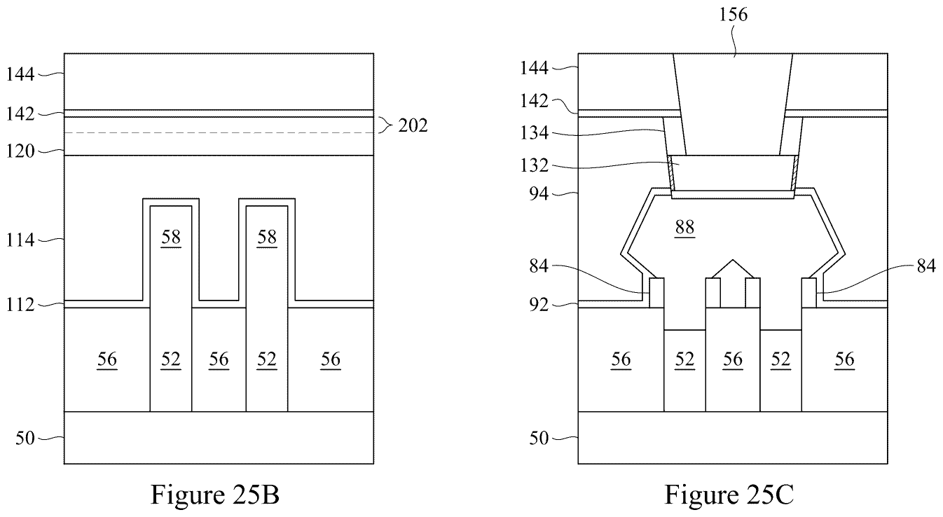

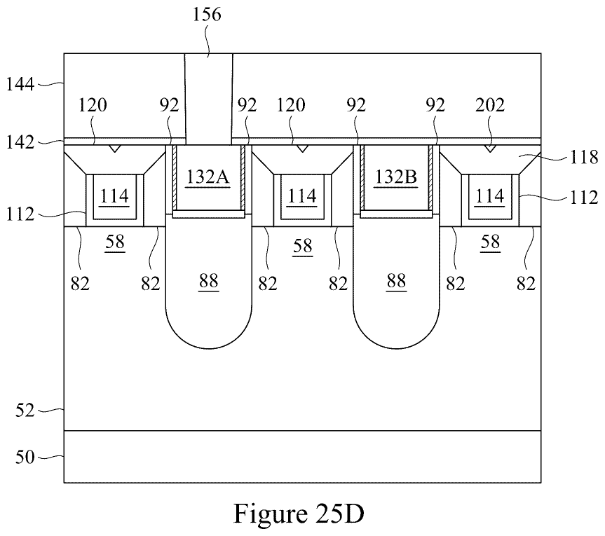

In FIGS. 25A-25D, a removal process is performed to remove excess portions of the conductive layer 154, which excess portions are over the top surfaces of the second ILD 144, to form upper source/drain contacts 156. FIG. 25A illustrates embodiments in which the removal process is performed on the structure relating to FIG. 24A. The removal process may also remove some portions of the second ILD 144. In some embodiments, a planarization process such as a CMP, an etch-back process, combinations thereof, or the like may be utilized. The remaining conductive layer 154 in the contact openings 152 form the upper source/drain contacts 156 in the contact openings 152. After the planarization process, the top surfaces of the second ILD 144 and the upper source/drain contacts 156 are coplanar (within process variations). The upper source/drain contacts 156 extend through the second ILD 144, the ESL 142, and the contact masks 134A (if present).

FIG. 25D illustrates embodiments in which the removal process is performed on the structure relating to FIG. 24D. Similarly as described above, the remaining conductive layer 154 in the contact openings 152 form the upper source/drain contacts 156, which extend through the second ILD 144, the ESL 142, and the contact masks 134A (if present). Note that FIGS. 25B and 25C may be applicable and analogous to these embodiments, albeit illustrating a different geometry of the various layers, as described above.

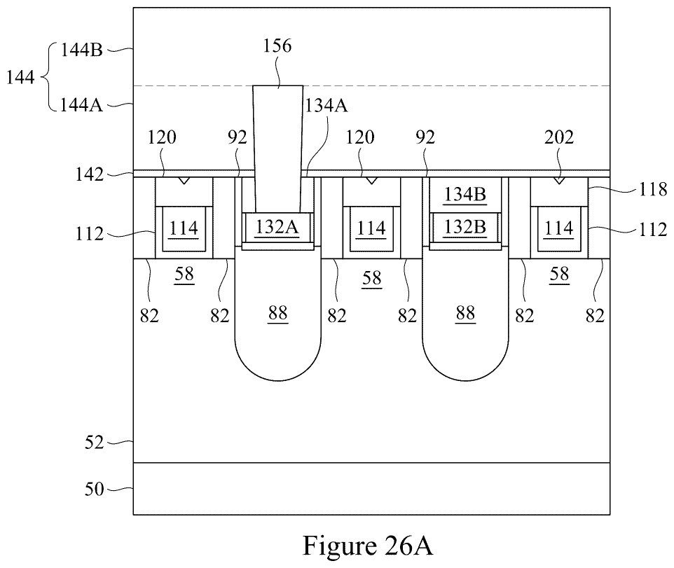

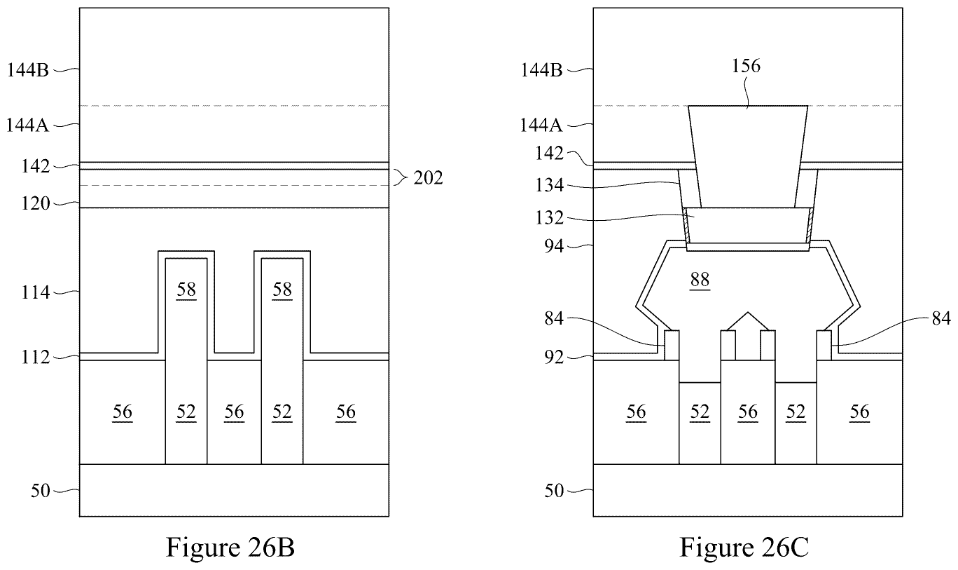

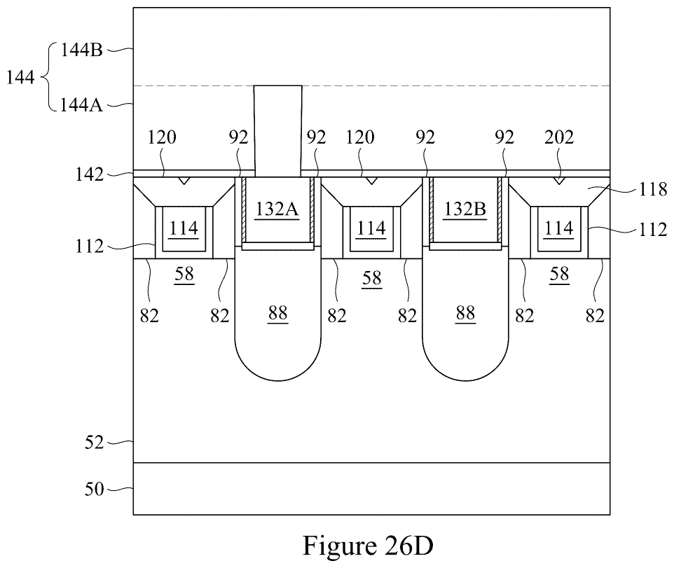

In FIGS. 26A-26D, additional portions of the material of the second ILD 144 are optionally redeposited on the upper source/drain contacts 156 and the original portions of the material of the second ILD 144. FIG. 26A illustrates embodiments in which the additional portions of the material of the second ILD 144 are formed over the structure relating to FIG. 25A. The second ILD 144 can thus include lower portions 144A (which include the original portions of the material of the second ILD 144) and upper portions 144B (which include the additional portions of the material of the second ILD 144).

FIG. 26D illustrates embodiments in which the additional portions of the material of the second ILD 144 are optionally redeposited over the structure relating to FIG. 25D. Similarly as described above, the second ILD 144 may comprise the lower portions 144A and the upper portions 144B. Note that FIGS. 26B and 26C may be applicable and analogous to these embodiments, albeit illustrating a different geometry of the various layers, as described above.

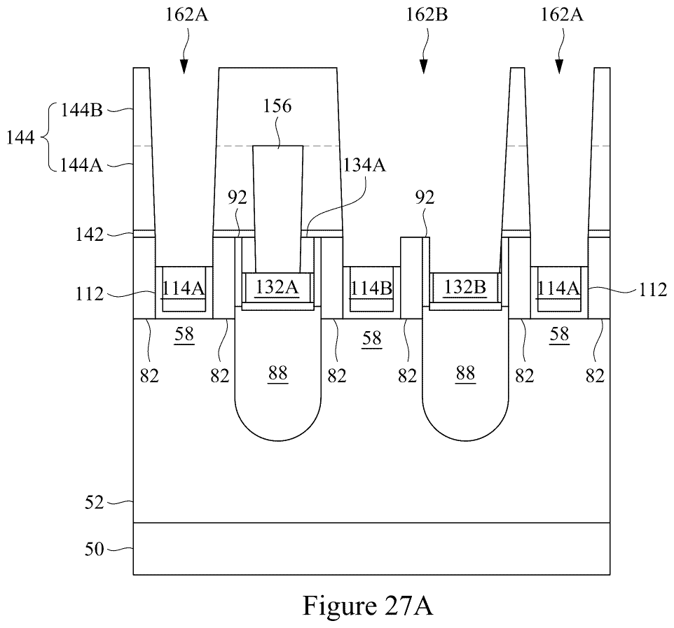

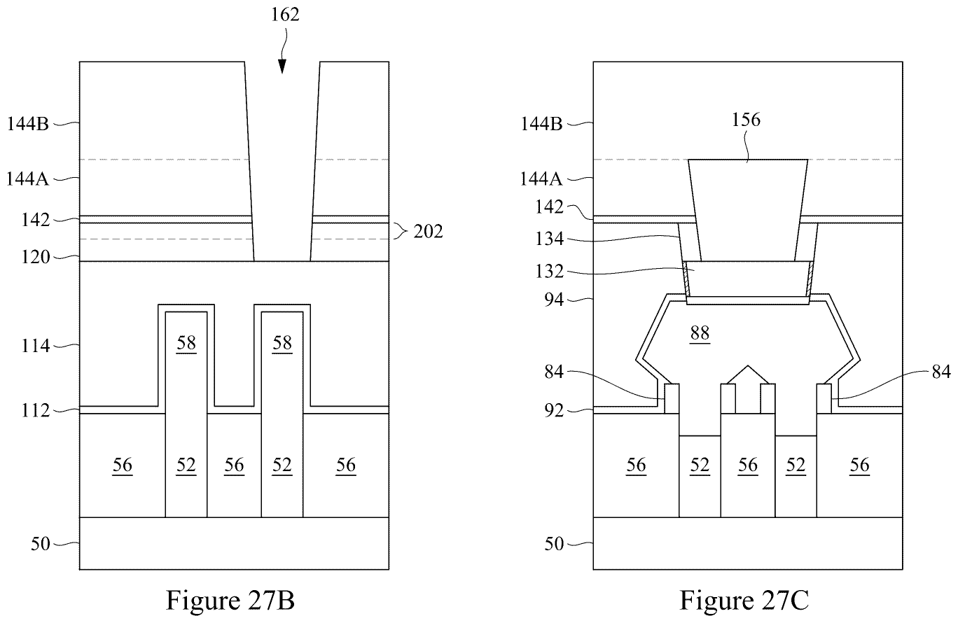

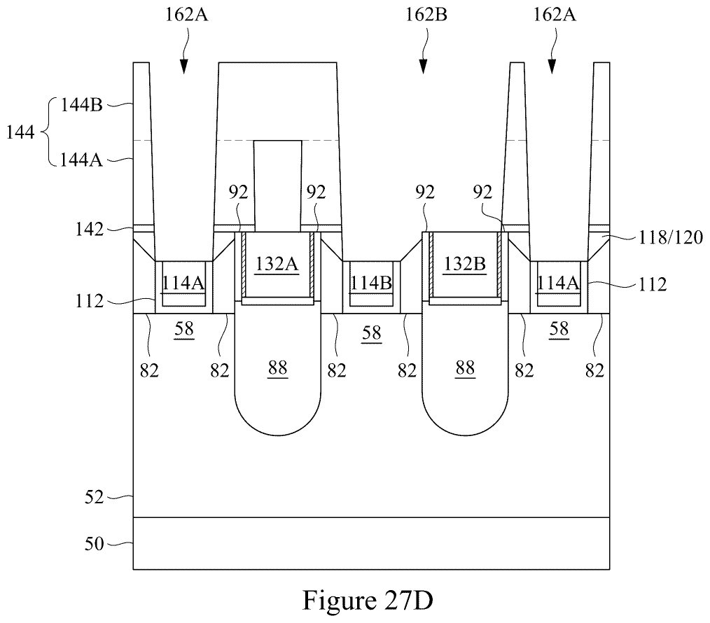

In FIGS. 27A-27D, contact openings 162 are formed through the second ILD 144, the ESL 142, and the gate masks 120. FIG. 27A illustrates embodiments in which the contact openings 162 are formed in the structure relating to FIG. 26A. A first subset of the contact openings 162A are formed to expose a first subset of the gate electrodes 114A, and a second subset of the contact openings 162B are formed to expose a second set of the gate electrodes 114B and adjacent lower source/drain contacts 132B. As illustrated, the contact openings 162B may further extend through or remove the contact masks 134B (if present) corresponding to the lower source/drain contacts 132B. The contact openings 162 may be formed using acceptable photolithography and etching techniques. The etching process may be anisotropic. For example, when the gate masks 120 are formed of silicon nitride, the etching process can be a dry etch performed with carbon tetrafluoride (CF₄), nitrogen trifluoride (NF₃), trifluoromethane (CHF₃), oxygen (O₂), hydrogen (H₂), argon (Ar), nitrogen (N₂), the like, combinations thereof, or a suitable etchant. The contact openings 162 expose the top surfaces of the gate electrodes 114 and the sidewalls of the gate spacers 82. In some embodiments (not specifically illustrated), upper portions of the gate spacers 82 and/or the CESL 92 may also be etched to expand the contact openings 162B.

As illustrated, the second subset of the contact openings 162B may be wider than the first subset of the contact openings 162A to expose the top surfaces of the gate electrodes 114B and the lower source/drain contacts 132B. In some embodiments, the contact openings 162B may be formed simultaneously with the contact openings 162A. In addition, in some embodiments, the contact openings 162B may be initially formed at similar widths as the contact openings 162A and subsequently widened using acceptable photolithography and etching techniques to extend through the contact masks 134B (if present) and expose the lower source/drain contacts 132B. The etching process may be anisotropic. For example, when the contact masks 134 are formed of silicon nitride, the etch can be a dry etch performed with carbon tetrafluoride (CF₄), the like, or a suitable dry etchant, and/or a wet etch performed with a suitable chelator, the like, or a suitable wet etchant. In accordance with some embodiments, the first subset of the contact openings 162A are not widened.

FIG. 27D illustrates embodiments in which the contact openings 162 to the gate electrodes 114 are formed in the structure relating to FIG. 26D. Similarly as described above, a first subset of the contact openings 162A are formed to expose a first subset of the gate electrodes 114A, and a second subset of the contact openings 162B are formed to expose a second subset of the gate electrodes 114B and the adjacent lower source/drain contacts 132B. Although not specifically illustrated, upper portions of the gate spacers 82 may also be etched to expand the contact openings 162B, such as between the lower source/drain contacts 132B and the gate electrodes 114B. In some embodiments, upper portions of the CESL 92 may also be removed. Note that FIGS. 27B and 27C may be applicable and analogous to these embodiments, albeit illustrating a different geometry of the various layers, as described above.

The etching process for removing portions of the gate spacers 82 may be different from the etching process(es) for initially forming the contact openings 162. For example, the etching process for removing portions of the gate spacers 82 may be performed by a different etching method and/or with different etching parameters or etchants. The gate spacers 82 may be removed using acceptable photolithography and etching techniques. The etching may be a wet or dry etch that is selective to the material of the gate spacers 82 (e.g., etches the material of the gate spacers 82 at a faster rate than the material(s) of the second ILD 144, the ESL 142, the gate electrodes 114, the gate dielectrics 112, the first ILD 94, the epitaxial source/drain regions 88, the fins 52, and, optionally, the CESL 92). For example, when the gate spacers 82 are formed of silicon nitride, the etching process can be a wet etch performed with phosphoric acid (H₃PO₄).

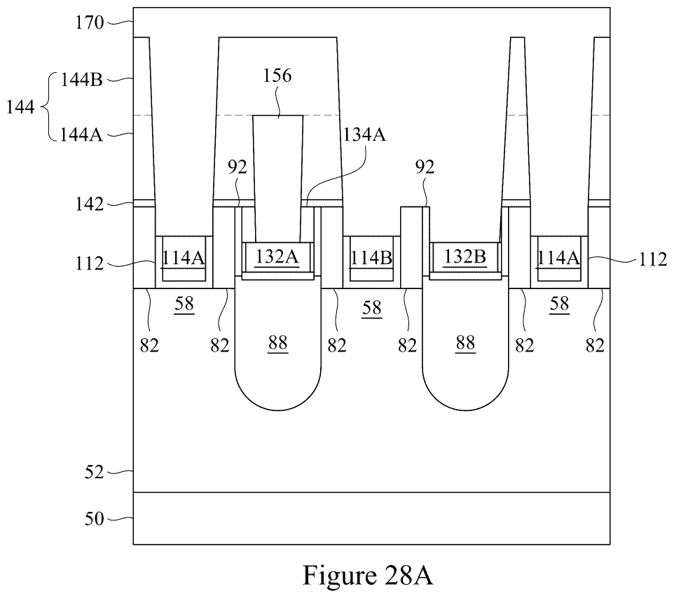

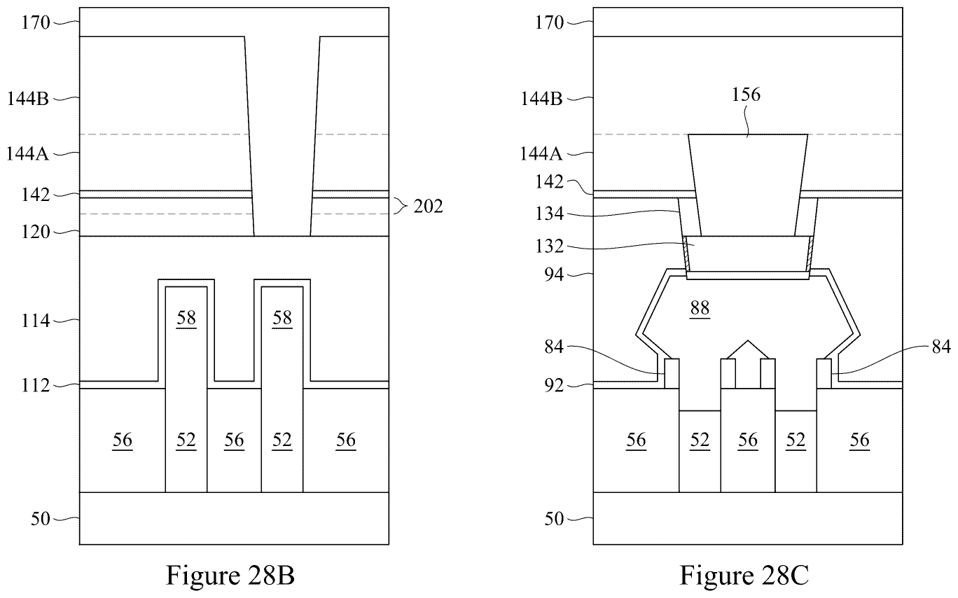

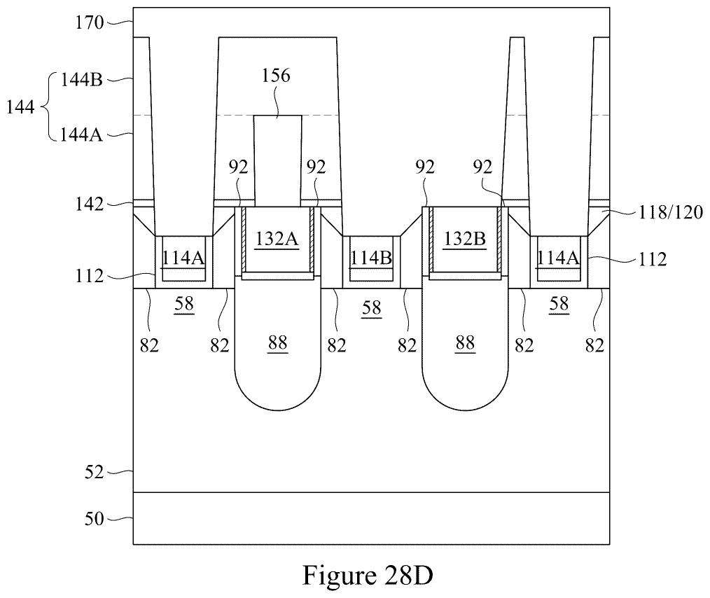

In FIGS. 28A-28D, a conductive layer 170 for gate contacts is formed in the contact openings 162. FIG. 28A illustrates embodiments in which the conductive layer 170 is formed over the structure relating to FIG. 27A. For example, the conductive layer 170 may include one or more layers and be formed by forming a liner (not separately illustrated), such as a diffusion barrier layer, an adhesion layer, and/or the like, and a conductive material in the contact openings 162. The liner may include titanium, titanium nitride, tantalum, tantalum nitride, or the like. The conductive material may be a metal such as copper, a copper alloy, silver, gold, tungsten, cobalt, aluminum, nickel, or the like, which may be formed by a deposition process such as PVD, ALD, CVD, or the like. The conductive layer 170 is formed on the sidewalls and/or top surfaces of the contact spacers 168, the second ILD 144, the gate electrodes 114, and the lower source/drain contacts 132B.

FIG. 28D illustrates embodiments in which the conductive layer 170 is formed in the contact openings 162 of the structure relating to FIG. 27D. Similarly as described above, the conductive layer 170 is formed on the sidewalls and/or top surfaces of the second ILD 144, the gate electrodes 114, and the lower source/drain contacts 132B. Note that FIGS. 28B and 28C may be applicable and analogous to these embodiments, albeit illustrating a different geometry of the various layers, as described above.

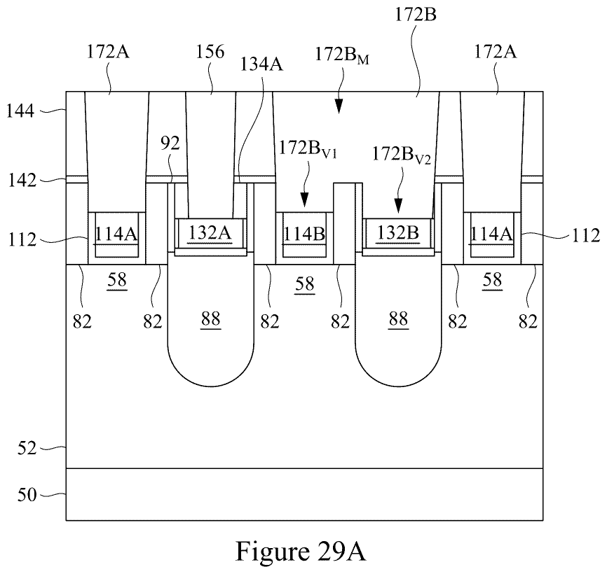

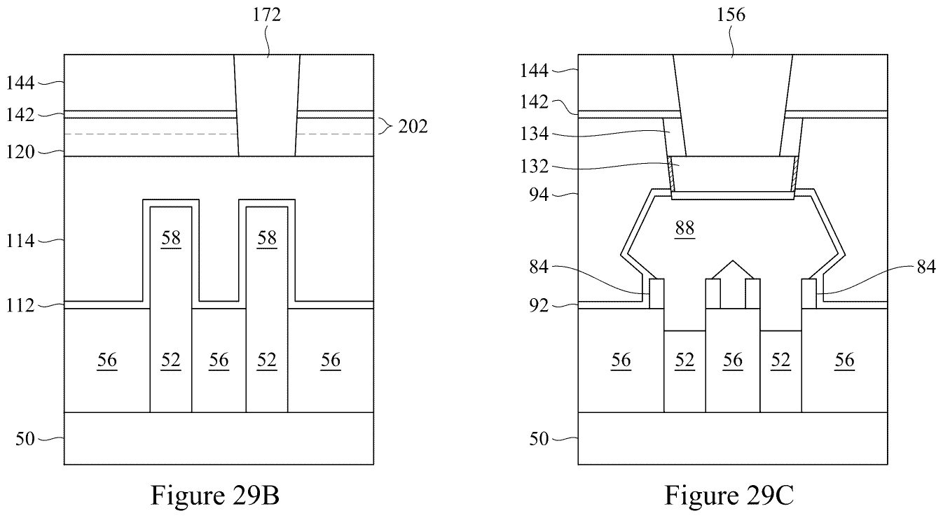

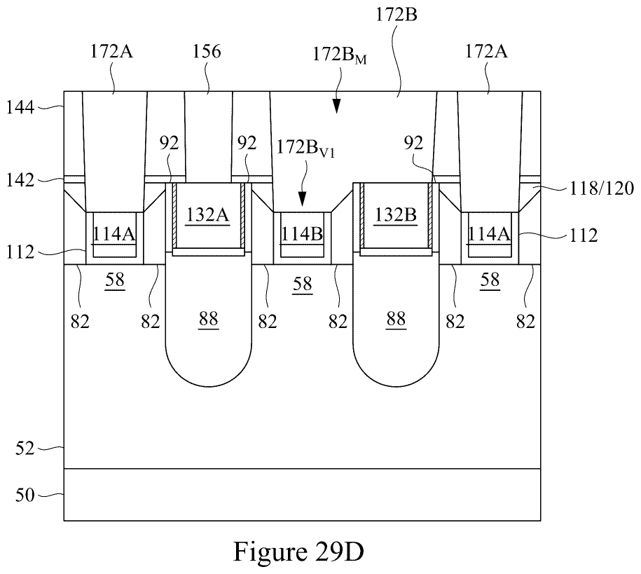

In FIGS. 29A-29D, a removal process is performed to remove excess portions of the conductive layer 170, which excess portions are over the top surfaces of the second ILD 144. FIG. 29A illustrates embodiments in which the removal process is performed on the structure relating to FIG. 28A. The removal process may also remove some portions of the second ILD 144, such as the portions over the top surfaces of the upper source/drain contacts 156. In some embodiments, a planarization process such as a CMP, an etch-back process, combinations thereof, or the like may be utilized. The remaining conductive layer 170 in the contact openings 162 forms gate contacts 172 in the contact openings 162. After the planarization process, the top surfaces of the second ILD 144, the upper source/drain contacts 156, and the gate contacts 172 may be coplanar (within process variations). The gate contacts 172 extend through the second ILD 144 and the ESL 142.

As illustrated, the first subset of the gate contacts 172A in the contact openings 162A are dedicated to particular gate electrodes 114A, and are not shared with the epitaxial source/drain regions 88. The second subset of the gate contacts 172B in the contact openings 162B are shared with a subset of the epitaxial source/drain regions 88 through the lower source/drain contacts 132B. According to various embodiments, the gate contacts 172B each have a main portion 172B_{M} extending through the second ILD 144 and the ESL 142, a first via portion 172B_{V1} extending through the gate mask 120 (or in the former location of the gate mask 120) to contact an underlying gate electrode 114B, and a second via portion 172B_{V2} extending through the contact mask 134B (or in the former location of the contact mask 134B) to contact a corresponding lower source/drain contact 132B. The gate spacers 82 may have portions that are beneath the main portion 172B_{M} of a gate contact 172B and between the via portions 172B_{V1}, 172B_{V2} of the gate contact 172B.

FIG. 29D illustrates embodiments in which the removal process is performed on the structure relating to FIG. 28D. Similarly as described above, the removal process separates the conductive layer 170 into the gate contacts 172A and the gate contacts 172B. In addition, the gate contacts 172B may have a main portion 172B_{M} and a first via portion 172B_{V1}, wherein the gate spacers 82 may have portions that are beneath the main portion 172B_{M}.

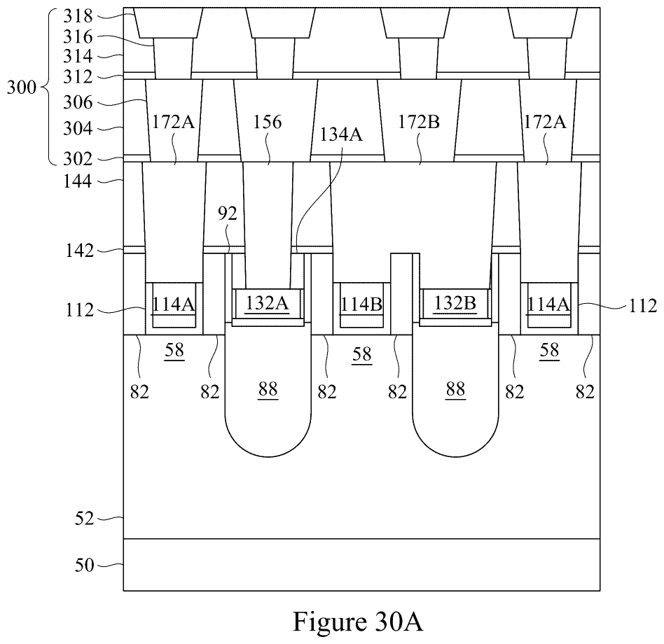

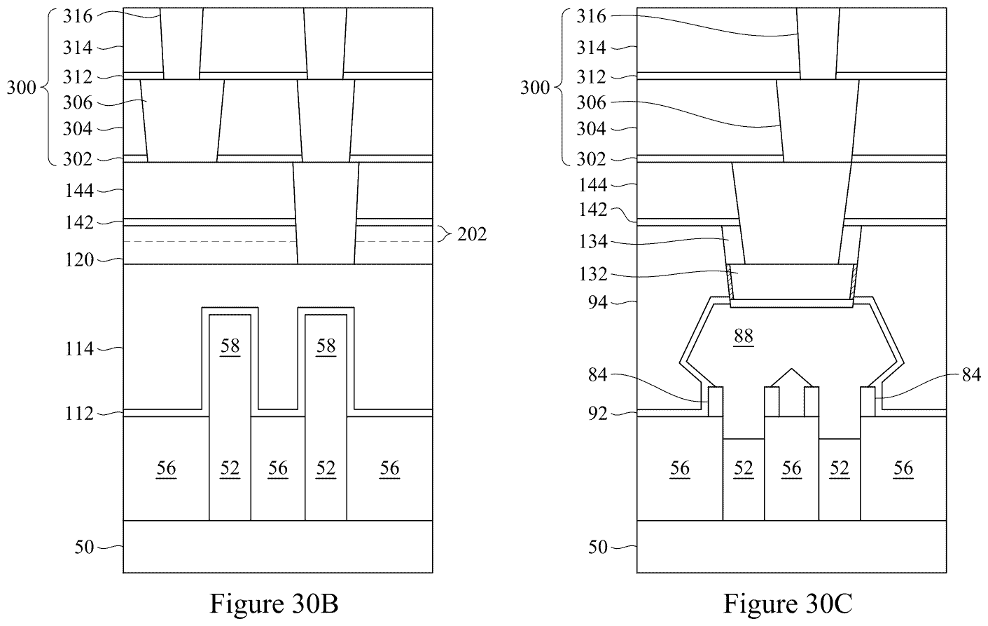

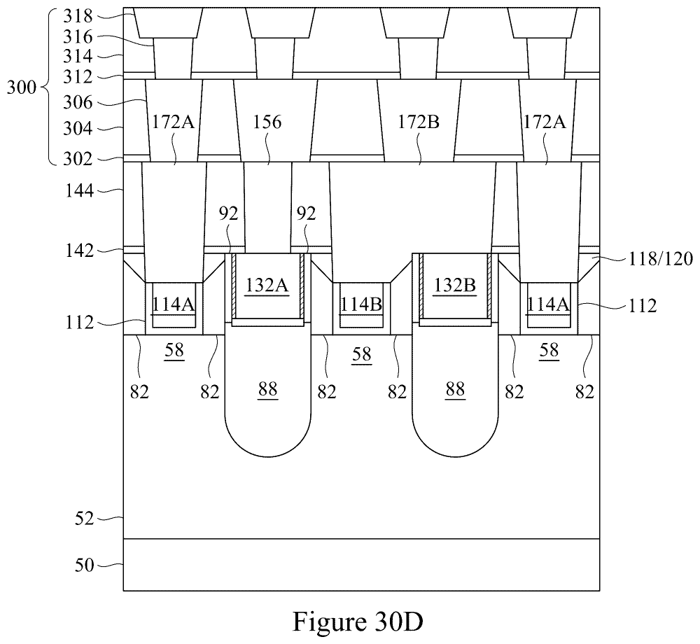

In FIGS. 30A-30D, a front-side interconnect structure 300 is formed over and electrically connected to the upper source/drain contacts 156 and to the gate contacts 172 to form an integrated circuit. FIG. 30A illustrates embodiments in which the front-side interconnect structure 300 is formed over the structure relating to FIG. 29A. The front-side interconnect structure 300 may include a plurality of metallization layers (e.g., conductive lines and conductive vias) embedded in a plurality of dielectric layers. For example, conductive lines 306 may be formed in a first inter-metal dielectric (IMD) 304, and conductive vias 316 and conductive lines 318 may be formed in a second IMD 314.

In accordance with some embodiments, the first IMD 304 and the second IMD 314 may each be deposited as a flowable film, such as being formed by a flowable CVD method. In some embodiments, the first IMD 304 and the second IMD 314 are formed of low-k dielectrics similar to materials that may be used in the first ILD 94 and the second ILD 144, such as PSG, BSG, BPSG, USG, silicon oxide, silicon nitride, polyimide, combinations thereof, or the like. The first IMD 304 and the second IMD 314 may be formed through processes such as CVD, ALD, PVD, spin-on processes, combinations thereof, or the like, although any suitable process may be utilized. The first IMD 304 and the second IMD 314 may be formed using the same or different materials and processes as one another. In some embodiments, an etch stop layer (ESL) 302 is formed between the first IMD 304 and the second ILD 144, the upper source/drain contacts 156, and the gate contacts 172. In addition, an ESL 312 may be formed between the second IMD 314 and the first IMD 304. The ESL 302 and the ESL 312 may each include a dielectric material, such as silicon nitride, silicon oxide, silicon oxynitride, or the like, having a high etch selectivity with the material of the first IMD 304 and the second IMD 314, respectively.

The conductive lines 306, the conductive vias 316, and the conductive lines 318 may be formed using one or more damascene processes, such as single damascene processes, dual damascene processes, or combinations thereof. For example, a single damascene process may be used to form the conductive lines 306 in the first IMD 304, and a dual damascene process may be used to form the conductive vias 316 and the conductive lines 318 in the second IMD 314.

In some embodiments, an opening and/or recess may be formed in and/or through the first IMD 304 (e.g., before forming the second IMD 314) using photolithography and one or more etching processes. Although not separately illustrated, a liner (e.g., a barrier layer, an adhesive layer, and/or the like) is conformally deposited in the opening and/or recess, and a conductive fill material is formed on the liner. The liner may comprise titanium nitride, titanium oxide, tantalum nitride, tantalum oxide, the like, or a combination thereof, and may be deposited by ALD, CVD, or another deposition technique. The conductive fill material may comprise copper, tungsten, cobalt, ruthenium, aluminum, gold, silver, alloys thereof, the like, or a combination thereof, and may be deposited by CVD, ALD, PVD, plating, or another deposition technique. After the conductive fill material is deposited, excess conductive fill material and liner may be removed by using a planarization process, such as a CMP.

The second IMD 314 may be formed over the first IMD 304 and the conductive lines 306. For example, a second single damascene process may be performed similarly as described above to form the conductive vias 316 and the conductive lines 318 in the second IMD 314.

FIG. 30D illustrates embodiments in which the front-side interconnect structure 300 is formed over the structure relating to FIG. 29D. Similarly as described above, the front-side interconnect structure 300 may include a plurality of metallization layers (e.g., the conductive lines 306, the conductive vias 316, and the conductive lines 318) embedded in a plurality of dielectric layers (e.g., the first IMD 304 and the second IMD 314).

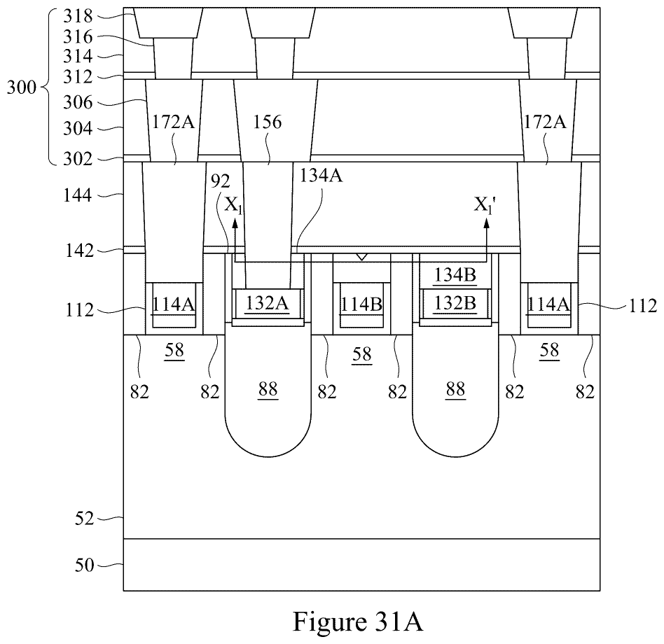

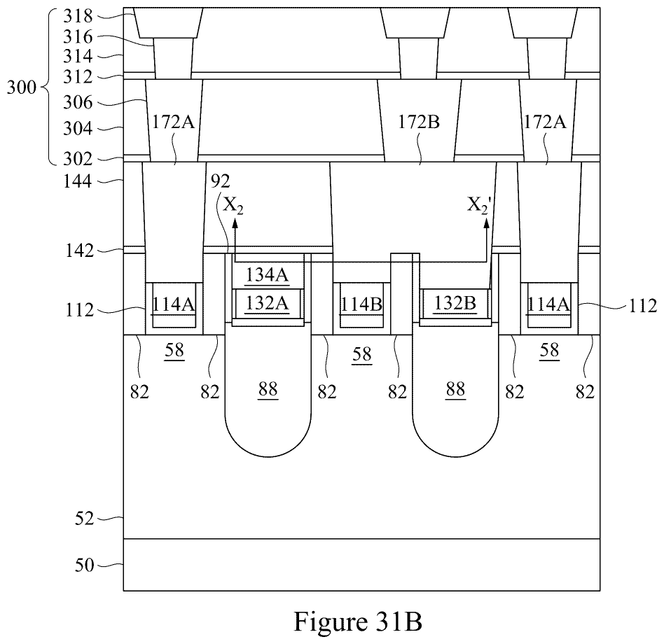

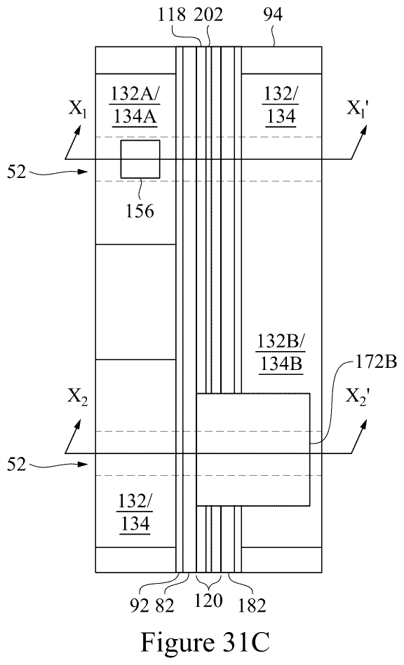

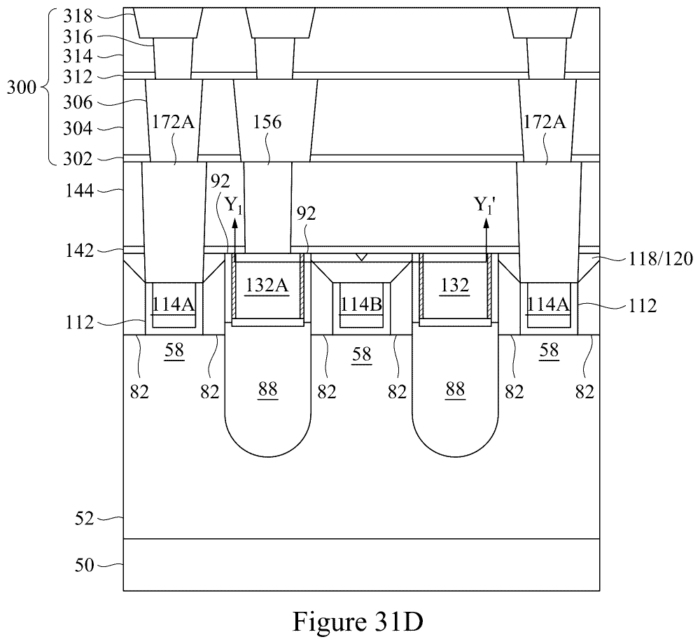

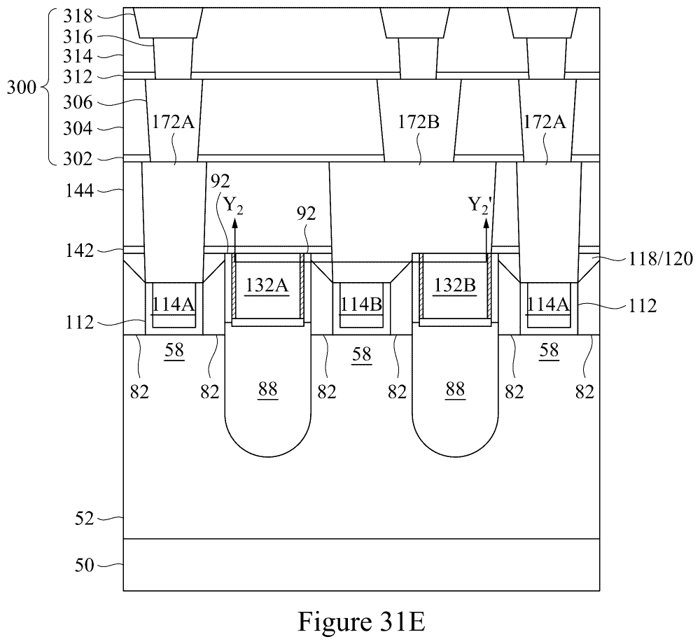

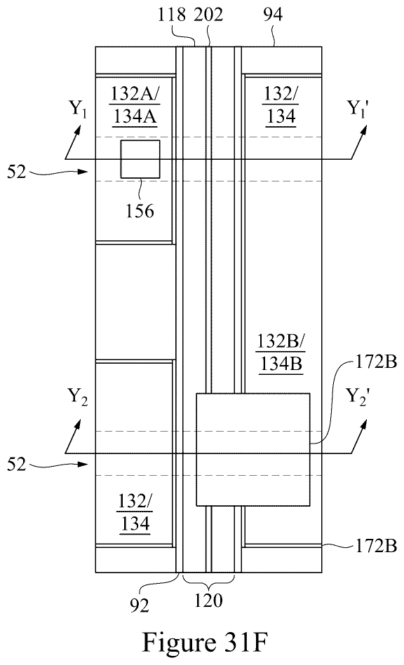

FIGS. 31A-31F are views of FinFETs, in accordance with some embodiments, illustrating that the source/drain contacts 156 and the gate contacts 172 may not be in the same cross-section. For example, FIGS. 31A and 31B illustrate example cross-sections of the embodiments relating to FIG. 30A, and FIG. 31C provides a top-down view of an exemplary layout containing those cross-sections, where some features of the FinFETs are omitted for illustration clarity. In particular, the lines X₁-X₁′ and X₂-X₂′ in FIG. 31C may correlate to the cross-sections of FIGS. 31A and 31B, respectively. As illustrated, the source/drain contacts 156 and the gate contacts 172 connected to a corresponding gate electrode 114 may not be in the same cross-section, and portions of the gate mask 120 (e.g., the dielectric layer 118 and the semiconductor layer 202) remain disposed over the gate structures in regions laterally displaced from the gate contacts 172.

Similarly, FIGS. 31D and 31E illustrate example cross-sections of the embodiments relating to FIG. 30D, and FIG. 31F provides a top-down view of an exemplary layout containing those cross-sections, where some features of the FinFETs are omitted for illustration clarity. In particular, the lines Y₁-Y₁′ and Y₂-Y₂′ in FIG. 31F may correlate to the cross-sections of FIGS. 31D and 31E, respectively. As illustrated, the source/drain contacts 156 and the gate contacts 172 connected to a corresponding gate electrode 114 may not be in the same cross-section, and portions of the gate mask 120 (e.g., the dielectric layer 118 and the semiconductor layer 202) remain disposed over the gate structures in regions laterally displaced from the gate contacts 172.

As illustrated, the semiconductor layer 202 may remain embedded in an upper portion of the dielectric layer 118, and the dielectric layer 118 and the semiconductor layer 202 may have level upper surfaces. The second ILD 144 (and the ESL 142) disposed over the gate masks 120 are conformal to those level upper surfaces. Referring to FIGS. 31A and 31B, for example, an upper surfaces of the gate spacers 82 may also be level with those upper surfaces of the dielectric layer 118 and the semiconductor layer 202. Referring to FIGS. 31D and 31E, for example, sidewalls of the dielectric layer 118 may be level with sidewalls of the gate spacers 82.

Embodiments may achieve advantages. Forming the gate masks 120 to include the dielectric layer 118 and the semiconductor layer 202 provides improved protection of the gate structures and increased efficiency and control in forming contacts to the epitaxial source/drain regions 88 and to the gate structures. For example, the semiconductor layer 202 may have a very high etch selectivity with the first ILD 94 during the etching of the contact openings 122 to form the lower source/drain contacts 132. As a result, the gate masks 120 remain substantially unetched and intact, including the dielectric layer 118 remaining covered and, therefore, also unetched and intact. In addition, the dual layer deposition of the dielectric layer 118 and the semiconductor layer 202 ensures that no voids or seams remain in the gate masks 120 during the etching of the contact openings 162 to form the gate contacts 172. As a result, etching through the gate masks 120 is performed with greater control and efficiency. The semiconductor devices (e.g., FinFETs) may be fabricated at a greater yield and resulting with improved reliability and performance.

The disclosed FinFET embodiments could also be applied to nanostructure devices such as nanostructure (e.g., nanosheet, nanowire, gate-all-around, or the like) field-effect transistors (NSFETs). In an NSFET embodiment, the fins are replaced by nanostructures formed by patterning a stack of alternating layers of channel layers and sacrificial layers. Dummy gate structures and source/drain regions are formed in a manner similar to the above-described embodiments. After the dummy gate structures are removed, the sacrificial layers can be partially or fully removed in channel regions. The replacement gate structures are formed in a manner similar to the above-described embodiments, the replacement gate structures may partially or completely fill openings left by removing the sacrificial layers, and the replacement gate structures may partially or completely surround the channel layers in the channel regions of the NSFET devices. ILDs and contacts to the replacement gate structures and the source/drain regions may be formed in a manner similar to the above-described embodiments. A nanostructure device can be formed as disclosed in U.S. Patent Application Publication No. 2016/0365414, which is incorporated herein by reference in its entirety.

Further, the FinFET/NSFET devices may be interconnected by metallization layers in an overlying interconnect structure to form integrated circuits. The overlying interconnect structure can be formed in a back end of line (BEOL) process, in which the metallization layers are connected to the upper source/drain contacts 156, and the gate contacts 172. Additional features, such as passive devices, memories (e.g., magnetoresistive random-access memory (MRAM), resistive random access memory (RRAM), phase-change random access memory (PCRAM), etc.), or the like may be integrated with the interconnect structure during the BEOL process.

In an embodiment, a method of forming a semiconductor device includes forming a source/drain region over a substrate; forming a first interlayer dielectric over the source/drain region; forming a gate structure over the substrate and laterally adjacent to the source/drain region; and forming a gate mask over the gate structure, the forming the gate mask comprising: etching a portion of the gate structure to form a recess relative to a top surface of the first interlayer dielectric; depositing a first dielectric layer over the gate structure in the recess and over the first interlayer dielectric; etching a portion of the first dielectric layer; depositing a semiconductor layer over the first dielectric layer in the recess; and planarizing the semiconductor layer to be coplanar with the first interlayer dielectric. In another embodiment, the method further includes forming a gate spacer over the substrate, wherein the etching the portion of the gate structure further comprises etching a portion of the gate spacer. In another embodiment, the etching the portion of the first dielectric layer comprises removing the first dielectric layer from over the first interlayer dielectric. In another embodiment, after depositing the first dielectric layer, the first dielectric layer comprises a first void located at a first height above the gate structure. In another embodiment, the etching the portion of the first dielectric layer comprises removing the first void. In another embodiment, after depositing the semiconductor layer, the semiconductor layer comprises a second void located at a second height above the gate structure, and wherein the second height is greater than the first height. In another embodiment, the method further includes etching the first interlayer dielectric to expose the source/drain region; and forming a lower source/drain contact over the source/drain region. In another embodiment, forming the lower source/drain contact includes conformally depositing a metal on the source/drain region and on the gate mask; and converting a first portion of the metal to a source/drain alloy region and a second portion of the metal to a gate mask alloy region. In another embodiment, the source/drain alloy region comprises a silicon-germanide, and wherein the gate mask alloy region comprises a silicide.

In an embodiment, a method of forming a semiconductor device includes forming a first dielectric layer over a source/drain region; forming a gate dielectric and a gate electrode laterally adjacent the first dielectric layer; etching the gate electrode to form a first recess above the gate electrode; conformally depositing a second dielectric layer in the first recess over the gate electrode; etching the second dielectric layer to partially re-form the first recess; depositing a semiconductor layer in the first recess over the second dielectric layer; and etching the first dielectric layer to expose the source/drain region, wherein the etching the first dielectric layer with an etchant that etches the semiconductor layer at a lower rate than the second dielectric layer. In another embodiment, the second dielectric layer comprises silicon nitride. In another embodiment, the semiconductor layer comprises silicon. In another embodiment, after conformally depositing the second dielectric layer, the second dielectric layer comprises a first void. In another embodiment, after depositing the semiconductor layer, the semiconductor layer comprises a second void. In another embodiment, the etching the first dielectric layer further comprises etching a portion of the semiconductor layer.

In an embodiment, a semiconductor device includes a gate electrode disposed between a first gate spacer and a second gate spacer; a dielectric layer disposed above the gate electrode and interposed between the first gate spacer and the second gate spacer; a semiconductor layer embedded in an upper portion of the dielectric layer, the dielectric layer and the semiconductor layer having level upper surfaces; and an interlayer dielectric disposed over and conformal to the level upper surfaces of the dielectric layer and the semiconductor layer. In another embodiment, a first sidewall of the dielectric layer is level with the first gate spacer, and wherein a second sidewall of the dielectric layer is level with the second gate spacer. In another embodiment, an upper surface of the first gate spacer is level with the level upper surfaces of the dielectric layer and the semiconductor layer. In another embodiment, the semiconductor device further includes a source/drain region disposed adjacent the first gate spacer; and a gate contact disposed over and electrically connected to the gate electrode and the source/drain region. In another embodiment, the semiconductor device further includes a source/drain mask disposed over the source/drain region, an upper surface of the source/drain mask being level with the level upper surfaces of the dielectric layer and the semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a gate electrode disposed between a first gate spacer and a second gate spacer;
a dielectric layer disposed above the gate electrode and interposed between the first gate spacer and the second gate spacer;
a semiconductor layer embedded in an upper portion of the dielectric layer, the dielectric layer and the semiconductor layer having level upper surfaces; and
an interlayer dielectric disposed over and conformal to the level upper surfaces of the dielectric layer and the semiconductor layer.

2. The semiconductor device of claim 1, wherein a first sidewall of the dielectric layer is level with the first gate spacer, and wherein a second sidewall of the dielectric layer is level with the second gate spacer.

3. The semiconductor device of claim 1, wherein an upper surface of the first gate spacer is level with the level upper surfaces of the dielectric layer and the semiconductor layer.

4. The semiconductor device of claim 1, further comprising:
a source/drain region disposed adjacent the first gate spacer; and
a gate contact disposed over and electrically connected to the gate electrode and the source/drain region.

5. The semiconductor device of claim 4, further comprising a source/drain mask disposed over the source/drain region, an upper surface of the source/drain mask being level with the level upper surfaces of the dielectric layer and the semiconductor layer.

6. The semiconductor device of claim 5, further comprising a lower source/drain contact disposed over the source/drain region, wherein the lower source/drain contact electrically couples the gate contact to the source/drain region.

7. The semiconductor device of claim 1, wherein in a cross-section an interface between the semiconductor layer and the dielectric layer has a V-shape.

8. The semiconductor device of claim 7, wherein the cross-section is perpendicular to a major plane of the gate electrode.

9. A semiconductor device, comprising:
a fin extending from a substrate;
a gate structure disposed over the fin, the gate structure comprising a gate dielectric and a gate electrode;
an epitaxial source/drain region disposed in the fin on a side of the gate structure;
a first interlayer dielectric disposed over the epitaxial source/drain region;
a gate mask disposed over the gate structure, the gate mask comprising a dielectric layer and a semiconductor layer embedded in an upper portion of the dielectric layer;
a second interlayer dielectric disposed over the gate mask and the first interlayer dielectric;
a source/drain contact extending through the second interlayer dielectric and the first interlayer dielectric to the epitaxial source/drain region; and
a front-side interconnect structure disposed over the second interlayer dielectric, the front-side interconnect structure comprising conductive lines and conductive vias electrically connected to the source/drain contact.

10. The semiconductor device of claim 9, wherein top surfaces of the dielectric layer and the semiconductor layer are substantially level.

11. The semiconductor device of claim 10, further comprising:
a first etch stop layer disposed between the first interlayer dielectric and the epitaxial source/drain region; and
a second etch stop layer disposed between the second interlayer dielectric and the gate mask, wherein the top surfaces of the dielectric layer and the semiconductor layer interface with the second etch stop layer.

12. The semiconductor device of claim 9, wherein the source/drain contact comprises a lower source/drain contact and an upper source/drain contact, wherein the lower source/drain contact extends through the first interlayer dielectric, and wherein the upper source/drain contact extends through the second interlayer dielectric.

13. The semiconductor device of claim 12, wherein the upper source/drain contact further extends through the first interlayer dielectric.

14. The semiconductor device of claim 12, further comprising a gate contact extending through the second interlayer dielectric and the gate mask to the gate electrode, wherein the gate contact is merged with the upper source/drain contact.

15. A semiconductor device comprising:
a gate structure disposed over and across a semiconductor fin, the gate structure comprising a gate dielectric and a gate electrode;
gate spacers disposed over the semiconductor fin and along opposite sides of the gate electrode;
source/drain regions disposed in the semiconductor fin on opposite sides of the gate spacers;
a first interlayer dielectric over the source/drain regions on opposite sides of the gate spacers; and
a gate mask over and along the gate structure, the gate mask comprising a semiconductor layer embedded in a dielectric layer.

16. The semiconductor device of claim 15, wherein the gate mask is disposed between the gate spacers.

17. The semiconductor device of claim 16, wherein the first interlayer dielectric interfaces with the gate spacers and the gate mask.

18. The semiconductor device of claim 15, further comprising an interconnect structure over the gate electrode and the source/drain regions, wherein a plurality of contact plugs electrically couples the gate electrode and the source/drain regions with the interconnect structure.

19. The semiconductor device of claim 18, wherein a first contact plug of the plurality of contact plugs electrically couples the gate electrode and a first source/drain region of the source/drain regions with the interconnect structure.

20. The semiconductor device of claim 19, further comprising:
a first source/drain mask over the first source/drain region;
a second source/drain region mask over a second source/drain region of the source/drain regions; and
a second contact plug of the plurality of contact plugs electrically coupling the second source/drain region with the interconnect structure.
